(19) United States
(12) Patent Application Publication
(10) Pub. No.: US 2010/0155844 A1
(43) Pub. Date: Jun. 24, 2010

(54) SEMICONDUCTOR DEVICE AND METHOD FOR MANUFACTURING THE SAME

(75) Inventor: Kensuke Takahashi, Tokyo (JP)

Correspondence Address: YOUNG & THOMPSON, 209 Madison Street, Suite 500, Alexandria, VA, 22314, US

(73) Assignee: NEC CORPORATION, Tokyo (JP)

(21) Appl. No.: 12/375,708

(22) PCT Filed: Jul. 25, 2007
(86) PCT No.: PCT/JP2007/064580

§ 371 Date: Jan. 30, 2009

(30) Foreign Application Priority Data
Aug. 1, 2006 (JP) 2006-210003

(51) Int. Cl. H01L 27/092; H01L 21/8238

(52) U.S. Cl. 257/348; 438/154; 257/E27.062; 257/E21.632

(57) ABSTRACT

There is provided a semiconductor device having excellent device characteristics in which Vₜₕ values of an nMOS transistor and a pMOS transistor are controlled to be desired values. The semiconductor device includes a pMOS transistor and an nMOS transistor formed by using an SOI substrate. The pMOS transistor is a fully depleted transistor including an n-type region, a first gate electrode, a first gate insulating film, and a source/drain region, and the nMOS transistor is a fully depleted transistor including a p-type region, a second gate electrode, a second gate insulating film, and a source/drain region. The first gate electrode includes silicide region comprising an NiSi crystalline phase containing an n-type impurity, the silicide region being in contact with the first gate insulating film, and the second gate electrode includes silicide region comprising an NiSi crystalline phase containing a p-type impurity, the silicide region being in contact with the second gate insulating film.

### TECHNICAL FIELD

The present invention relates to a semiconductor device including a fully depleted nMOS transistor and pMOS transistor formed by using an SOI substrate. The present invention also relates to a low-power semiconductor device in which Vₜₕ (threshold voltage) values of the MOS transistors are controlled to exhibit excellent device characteristics.

### BACKGROUND ART

There has proposed a semiconductor device including an nMOS transistor and a pMOS transistor, each of which includes a metal gate electrode made of a metal or other materials. Such a semiconductor device including a MOS transistor with a metal gate electrode is characterized in that the gate electrode will not be depleted even when the transistor is miniaturized, whereby sufficient drive current (Iₒₙ) is provided.

FIG. 1 shows such a semiconductor device. The semiconductor device shown in FIG. 1 includes planar nMOS transistor 21 and pMOS transistor 22. In the semiconductor device, p-type region 23 and n-type region 24 are present in silicon substrate 1.

N-type source/drain region 5 is present in p-type region 23, and silicide layer 6 is provided on source/drain regions 5. Gate electrode 8 is provided above part of p-type region 23 with gate insulating film therebetween. Further, gate sidewall 7 is provided on the side of gate electrode 8. P-type region 23, source/drain region 5, gate insulating film 3, and gate electrode 8 form nMOS transistor 21.

Similarly, p-type source/drain region 5 is provided in n-type region 24. Gate insulating film 3 and gate electrode 9 are provided on part of n-type region 24, and gate sidewall 7 is provided on the side of gate electrode 9. N-type region 24, source/drain region 5, gate insulating film 3, and gate electrode 9 form pMOS transistor 22.

In the semiconductor device including the planar MOS transistors shown in FIG. 1, it is a conventional practice to control Vₜₕ values of the MOS transistors by changing the materials of the metals that form gate electrodes 8 and 9 and impurity concentration, or when gate electrodes 8 and 9 are made of alloys, changing the composition ratio of each of the alloys (dual work function metal gate technology).

A seventh exemplary embodiment in Japanese Patent Laid-Open No. 2004-221226 discloses a semiconductor device including a partially depleted nMOS transistor and pMOS transistor using a bulk substrate. In the semiconductor device, the gate electrode of the nMOS transistor is made of NiSi containing As and the gate electrode of the pMOS transistor is made of NiSi containing B, whereby Vₜₕ of each of the gate electrodes is controlled.

FIG. 10 shows another example of a related semiconductor device. The semiconductor device shown in FIG. 10 includes fin-type MOS transistors including protruding semiconductor regions 23 and 24 protruding upward from embedded oxide film 11, and channel regions to be formed in the semiconductor regions. The semiconductor device comprises nMOS transistor 21 and pMOS transistor 22. In the semiconductor device, two protruding p-type region 23 and n-type region 24 are formed on embedded oxide film 11. Gate electrodes 8 and 9 are formed on both sides of p-type region 23 and n-type region 24, respectively.

N-type source/drain region 30a is formed in the both portions of protruding p-type region 23 sandwiching gate electrode 8, and p-type source/drain region 30b is formed in the both portions of protruding n-type region 24 sandwiching gate electrode 9. Gate insulating films 3a and 3b are formed between p-type region 23 and gate electrode 8 and between n-type region 24 and gate electrode 9, respectively.

P-type region 23, source/drain region 30a, gate insulating layer 3a, and gate electrode 8 form nMOS transistor 21. Similarly, n-type region 24, source/drain region 30b, gate insulating layer 3b, and gate electrode 9 form pMOS transistor 22.

When MOS transistors 21 and 22 shown in FIG. 10 are in operation, channel regions are to be formed on the sides of p-type region 23 and n-type region 24.

In the semiconductor device comprising fin-type MOS transistors shown in FIG. 10 as well, it is a conventional practice to control Vₜₕ values of the MOS transistors by changing the materials of the metals that form gate electrodes 8 and 9 and impurity concentration, or when gate electrodes 8 and 9 are made of alloys, changing the composition ratio of each of the alloys (dual work function metal gate technology).

In the planar MOS transistor and the fin-type MOS transistor described above, the semiconductor region in which a channel region is to be formed (body region) is thick (the length in the direction indicated by reference numeral 25 in FIG. 1 and the length in the direction indicated by reference numeral 26 in FIG. 10 are large). Each of the MOS transistors described above therefore functions as a partially depleted MOS transistor (PD-MOSFET) in which the body region is partially depleted during operation.

In recent years, as mobile phone terminals and other apparatus have been equipped with increasingly advanced functions and used in increasingly various applications, there has been a demand for a low-power, high-speed device. As a low-power, high-speed semiconductor device, a semiconductor device including a fully depleted MOS transistor (FD-MOSFET) in which the body region is fully depleted during operation has received attention.

A semiconductor device including such a MOS transistor can (1) operate at a lower power level due to improvement in S (sub-threshold swing) value, and (2) consume less power due to reduction in substrate leak current. The semiconductor device can also (3) be faster due to reduction in substrate parasitic capacitance, and (4) operate at a higher speed due to reduction in channel dose (impurity concentration of 1×10¹⁴ to 1×10¹⁶ cm⁻³) (improvement in mobility in a working voltage area). The device characteristics can therefore be greatly improved. Among the above device characteristics, the advantageous effect described in (4) allows the short channel effect in a low-channel-dose area to be suppressed, which is a significant advantage obtained by using a fully depleted MOS transistor.

### DISCLOSURE OF THE INVENTION

As described above, a semiconductor device including a fully depleted MOS transistor with a metal gate electrode can operate at a low power level and improve mobility (operate at high speed) by lowering the channel dose. Lowering the channel dose, however, disadvantageously makes it difficult to control Vₜₕ.

Specifically, to achieve a low-power semiconductor device, it is necessary to set Vₜₕ of a pMOS transistor to a value ranging from approximately −0.6 to −0.3 V and Vₜₕ of an nMOS transistor to a value ranging from approximately 0.3 to 0.6 V. It is, however, very difficult to control the Vₜₕ values to fall within the above ranges by using the technology disclosed in Japanese Patent Laid-Open No. 2004-221226. The reason of this will be described below in detail.

(1) FIGS. 11 and 12 show a related method for manufacturing a semiconductor device including a MOSFET with a polysilicon gate electrode formed by using a bulk substrate. In the manufacturing method, silicon substrate 1 including p-type region 23 and n-type region 24 is first prepared. Isolation region 2 is then formed in silicon substrate 1. After insulating film layer 85 and polysilicon layer 86 are deposited (FIG. 11(a)), the insulating film layer 85 and the polysilicon layer 86 are patterned to form gate electrode materials including polysilicon region 29a on gate insulating film 3a and polysilicon region 29b on gate insulating film 3b (FIG. 11(b)). Ion plantation is then carried out to form extension regions 4a and 4b in silicon substrate (1) (FIG. 11(c)).

Further, after a silicon oxide film is deposited, the structure is etched back to form gate sidewalls 7 on the sides of polysilicon regions 29a and 29b (FIG. 12(a)). After mask 27 is formed over n-type region 24 in silicon substrate 1, mask 27 and gate sidewall 7 are used as a mask to implant an n-type impurity. In this step, an n-type impurity is implanted on both sides of the silicon substrate sandwiching polysilicon region 29a and gate sidewall 7 at the same time to form source/drain region 30a on both sides of gate sidewall 7 in the silicon substrate (FIG. 12(b)).

After mask 27 is removed, mask 28 is formed on p-type region 23 in silicon substrate 1. Mask 28 and gate sidewall 7 are then used as a mask to implant a p-type impurity. In this step, a p-type impurity is implanted on both sides of the silicon substrate sandwiching polysilicon region 29b and gate sidewall 7 at the same time to form source/drain region 30b on both sides of gate sidewall 7 (FIG. 12(c)).

In the related method for manufacturing a semiconductor device, impurity implantation to form the source/drain region and impurity implantation to form the gate electrode are carried out at the same time. Therefore, the impurity implanted into the source/drain region is the same as that implanted into the gate electrode, and the type of the impurity is limited.

The same situation applies to a fully depleted MOS transistor with a polysilicon gate electrode. That is, the same type of impurity element is implanted into the source/drain region and the gate electrode, as in the MOS transistor using a bulk substrate described above. As a result, it is difficult to set Vₜₕ necessary for a low-power semiconductor device.

FIG. 2 shows, by the dotted lines, results of computer simulation of the relationship between the channel impurity concentration and Vₜₕ for conventional partially depleted MOS transistors, each of which is formed by using a bulk substrate (silicon substrate) and includes either a polysilicon gate electrode or an NiSi gate electrode. The solid lines in FIG. 2 represent results of computer simulation of the relationship between the channel impurity concentration and Vₜₕ for fully depleted MOS transistors, each of which is formed by using an SOI substrate.

FIG. 2(a) shows pMOS transistors, each of which includes an NiSi electrode containing either B or P as an impurity (B/P doped NiSi) or a polysilicon electrode containing either B or P as an impurity (B/P doped poly-Si). FIG. 2(b) shows nMOS transistors, each of which includes an NiSi electrode containing either B or P as an impurity (B/P doped NiSi) or a polysilicon electrode containing either B or P as an impurity (B/P doped poly-Si). In the polysilicon gate electrodes and the NiSi gate electrodes of the MOS transistors containing B or P as an impurity, the corresponding impurity is added at a concentration of 5×10²⁰ cm⁻³ in advance to the polysilicon before silicidation. For the partially depleted MOS transistors (dotted lines), the gate length is 0.3 μm and the physical film thickness (converted into an SiO₂ film thickness) of the gate insulating film is 1.6 nm. For the fully depleted MOS transistors (solid lines), the gate length is 0.3 μm, the thickness of the semiconductor layer in which a channel region is to be formed is 15 nm, and the physical film thickness (converted into an SiO₂ film thickness) of the gate insulating film is 1.6 nm.

For example, for the fully depleted pMOS transistor with the gate electrode made of B-doped poly-Si (polysilicon), as indicated by the solid line in FIG. 2(a), Vₜₕ is greater than 0 V in a low-channel-dose area (1×10¹⁷ cm⁻³ or lower). When the gate electrode is thus configured, Vₜₕ cannot be controlled to be a value within the range between −0.6 and −0.3 V, which is necessary for a low-voltage pMOS transistor.

Further, for the fully depleted pMOS transistor with the NiSi gate electrode containing B as the p-type impurity, as indicated by the solid line in FIG. 2(a), Vₜₕ ranges from approximately −0.2 to −0.1 V in the low-channel-dose area (1×10¹⁷ cm⁻³ or lower). When the gate electrode is thus configured, Vₜₕ cannot be controlled to be a value within the range between −0.6 and −0.3 V, which is necessary for a low-voltage pMOS transistor.

Similarly, for the fully depleted nMOS transistor with the gate electrode made of P-doped poly-Si (polysilicon), as indicated by the solid line in FIG. 2(b), Vₜₕ is smaller than 0 V in the low-channel-dose area (1×10¹⁷ cm⁻³ or lower). Therefore, Vₜₕ cannot be controlled to be a value within the range between 0.6 and 0.3 V, which is necessary for a low-voltage pMOS transistor.

Further, for the fully depleted nMOS transistor with the NiSi gate electrode containing P as the n-type impurity, as indicated by the solid line in FIG. 2(b), Vₜₕ ranges from approximately 0.1 to 0.2 V in the low-channel-dose area (1×10¹⁷ cm⁻³ or lower). When the gate electrode is thus configured, Vₜₕ cannot be controlled to be a value within the range between 0.3 and 0.6 V, which is necessary for a low-voltage pMOS transistor.

Therefore, in the related semiconductor technology, when applied to a low-channel-dose, fully depleted device, it is not easy to control Vₜₕ to be a value appropriate for a low-power device. Further, materials that can be used as the gate electrode material are limited from the viewpoint of complicated device manufacturing processes, so that there is a limit in controlling Vₜₕ of a MOS transistor by controlling the gate electrode material.

(2) FIG. 3(a) shows the relationship in a pMOS transistor between the concentration of a dopant (B) implanted into the gate electrode and an effective work function, and FIG. 3(b) shows the relationship in an nMOS transistor between the concentration of a dopant (P) implanted into the gate electrode and an effective work function. FIG. 3 shows that the range of the effective work function modulated with respect to the dopant concentration is approximately ±0.15 eV at the maximum in each of the MOS transistors. Such a narrow effective work function modulation range leads to a narrow Vₜₕ modulation range accordingly. Therefore, even when the concentration of B in an NiSi electrode of the pMOS transistor and the concentration of P in an NiSi electrode of the nMOS transistor are changed, it is difficult to set Vₜₕ to a value within the range between ±0.6 and 0.3 V necessary for a low-voltage MOS transistor. It is thus difficult to directly apply the related technology described above to a semiconductor device including a fully depleted MOS transistor.

(3) Further, as indicated by the dotted lines in FIG. 2(a), Vₜₕ greatly decreases as the channel impurity concentration increases in the pMOS transistor. As indicated by the dotted lines in FIG. 2(b), Vₜₕ greatly increases as the channel impurity concentration increases in the nMOS transistor.

In contrast, as indicated by the solid lines in FIG. 2(a), the Vₜₕ values of the SOI-substrate-based fully depleted pMOS transistors do not decrease as the channel impurity concentration increases as greatly as those of the bulk-substrate-based pMOS transistors. Similarly, as indicated by the solid lines in FIG. 2(b), the Vₜₕ values of the nMOS transistors do not increase as the channel impurity concentration increases as greatly as those of the bulk-substrate-based nMOS transistors.

As described above, an SOI-substrate-based fully depleted MOS transistor greatly differs from a bulk-substrate-based partially depleted MOS transistor in terms of the relationship between the amount of channel dose and Vₜₕ. This reason is that the thickness of a silicon layer for the channel region in a fully depleted MOS transistor differs from that in a partially depleted MOS transistor, so that the intensity of the electric field applied to the silicon layer to form the channel region when a gate voltage is applied in the fully depleted MOS transistor significantly differs from that in the partially depleted MOS transistors.

As described in the above (1) to (3), it is very difficult to control Vₜₕ by applying the technology for controlling Vₜₕ of a partially depleted MOS transistor to a fully depleted MOS transistor.

The present inventor has intensively conducted studies on a variety of metal gate electrode materials and found that NiSi containing a specific impurity may be preferably used as the material that forms the gate electrode of each of the pMOS and nMOS transistors. That is, the present inventor has found that in the thus configured semiconductor device, Vₜₕ values of the nMOS and pMOS transistors can be controlled to values necessary for a low-power device and the nMOS and pMOS transistors can be operated at a higher speed, whereby a semiconductor device with excellent device characteristics can be provided.

To solve the above problem, the present invention is characterized by the following configurations.

The present invention relates to a semiconductor device, comprising:

a support substrate;

an oxide film formed on the support substrate; and

pMOS transistor and an nMOS transistor formed on the oxide film,

wherein the pMOS transistor is a fully depleted transistor,

the pMOS transistor comprising:

an n-type region formed on the oxide film;

a first gate electrode formed above the n-type region;

a first gate insulating film formed between the n-type region and the first gate electrode; and

a source/drain region formed throughout in both portions of the n-type region sandwiching the first gate electrode in the direction of a normal to the surface where the n-type region is in contact with the first gate insulating film,

the nMOS transistor is a fully depleted transistor,

the nMOS transistor comprising:

a p-type region formed on the oxide film;

a second gate electrode formed above the p-type region;

a second gate insulating film formed between the p-type region and the second gate electrode; and

a source/drain region formed throughout in both portions of the p-type region sandwiching the second gate electrode in the direction of a normal to the surface where the p-type region is in contact with the second gate insulating film,

the first gate electrode includes silicide region (1) comprising an NiSi crystalline phase containing an n-type impurity, the silicide region (1) being in contact with the first gate insulating film, and

the second gate electrode includes silicide region (2) comprising an NiSi crystalline phase containing a p-type impurity, the silicide region (2) being in contact with the second gate insulating film.

The present invention relates to a semiconductor device, comprising:

a support substrate;

an oxide film formed on the support substrate; and

a pMOS transistor and an nMOS transistor formed on the oxide film,

wherein the pMOS transistor comprises:

an n-type region formed on the oxide film;

a first gate electrode formed above the n-type region;

a first gate insulating film formed between the n-type region and the first gate electrode; and

a source/drain region formed throughout in both portions of the n-type region sandwiching the first gate electrode in the direction of a normal to the surface where the n-type region is in contact with the first gate insulating film,

the length of the n-type region in the direction of the normal to the surface where the n-type region is in contact with the first gate insulating film is one-fourth of a gate length of the pMOS transistor or smaller,

the first gate electrode includes silicide region (1) comprising an NiSi crystalline phase containing an n-type impurity, the silicide region (1) being in contact with the first gate insulating film,

the nMOS transistor comprises:

a p-type region formed on the oxide film;

a second gate electrode formed above the p-type region;

a second gate insulating film formed between the p-type region and the second gate electrode; and

a source/drain region formed throughout in both portions of the p-type region sandwiching the second gate electrode in the direction of a normal to the surface where the p-type region is in contact with the second gate insulating film,

the length of the p-type region in the direction of the normal to the surface where the p-type region is in contact with the second gate insulating film is one-fourth of a gate length of the nMOS transistor or smaller, and

the second gate electrode includes silicide region (2) comprising an NiSi crystalline phase containing a p-type impurity, the silicide region (2) being in contact with the second gate insulating film.

The present invention relates to a semiconductor device, comprising:

a support substrate;

an oxide film formed on the support substrate;

a semiconductor layer formed on the oxide film;

a fully depleted pMOS transistor comprising an n-type region formed in the semiconductor layer, a first gate electrode formed above the n-type region, a first gate insulating film formed between the n-type region and the first gate electrode, and a source/drain region formed throughout in both portions of the n-type region sandwiching the first gate electrode in the direction of a normal to the surface where the n-type region is in contact with the first gate insulating film; and

a fully depleted nMOS transistor comprising a p-type region formed in the semiconductor layer, a second gate electrode formed above the p-type region, a second gate insulating film formed between the p-type region and the second gate electrode, and a source/drain region formed throughout in both portions of the p-type region sandwiching the second gate electrode in the direction of a normal to the surface where the p-type region is in contact with the second gate insulating film,

wherein the first gate electrode includes silicide region (1) comprising an NiSi crystalline phase containing an n-type impurity, the silicide region (1) being in contact with the first gate insulating film, and

the second gate electrode includes silicide region (2) comprising an NiSi crystalline phase containing a p-type impurity, the silicide region (2) being in contact with the second gate insulating film.

The present invention relates to a semiconductor device, comprising:

a support substrate;

an oxide film formed on the support substrate;

a fully depleted pMOS transistor including a protruding n-type region protruding from the oxide film, a first gate electrode formed on both sides of the protruding n-type region, a first gate insulating film formed between the n-type region and the first gate electrode, and a source/drain region formed throughout in both portions of the n-type region sandwiching the first gate electrode in the direction of a normal to the surface where the n-type region is in contact with the first gate insulating film; and

a fully depleted nMOS transistor including a protruding p-type region protruding from the oxide film, a second gate electrode formed on both sides of the protruding p-type region, a second gate insulating film formed between the p-type region and the second gate electrode, and a source/drain region formed throughout in both portions of the p-type region sandwiching the second gate electrode in the direction of a normal to the surface where the p-type region is in contact with the second gate insulating film,

wherein the first gate electrode includes silicide region (1) comprising an NiSi crystalline phase containing an n-type impurity, the silicide region (1) being in contact with the first gate insulating film, and

the second gate electrode includes silicide region (2) comprising an NiSi crystalline phase containing a p-type impurity, the silicide region (2) being in contact with the second gate insulating film.

The present invention relates to a method for manufacturing the semiconductor device, the method comprising:

preparing a substrate in which the support substrate, the oxide film, and a semiconductor layer with the n-type region and the p-type region are sequentially stacked;

depositing an insulating film and a polysilicon layer over the surface;

forming mask (A) on the polysilicon layer formed on the n-type region;

using the mask (A) as a mask to implant a p-type impurity into the polysilicon layer;

removing the mask (A);

forming mask (B) on the polysilicon layer formed on the p-type region;

using the mask (B) as a mask to implant an n-type impurity into the polysilicon layer;

removing the mask (B);

forming a mask layer on the polysilicon layer;

patterning the insulating film, the polysilicon layer, and the mask layer to form the first gate insulating film, a first gate electrode material, and mask (C) on the n-type region and the second gate insulating film, a second gate electrode material, and mask (C) on the p-type region;

forming gate sidewalls on the sides of the first gate insulating film, the first gate electrode material, and the mask (C) and on the sides of the second gate insulating film, the second gate electrode material, and the mask (C);

forming mask (D) over the surface of the n-type region;

using the masks (C) and (D) and the gate sidewall as a mask to implant an n-type impurity into the p-type region;

removing the mask (D);

forming mask (E) over the surface of the p-type region;

using the masks (C) and (E) and the gate sidewall as a mask to implant a p-type impurity into the n-type region;

removing the mask (E);

forming the source/drain regions in the p-type and n-type regions by carrying out heat treatment to activate the n-type impurity implanted into the p-type region and the p-type impurity implanted into the n-type region, as a formation step;

depositing an interlayer insulating film over the surface;

removing the mask (C) and part of the interlayer insulating film to expose the first and second gate electrode materials;

depositing an Ni layer on the exposed first and second gate electrode materials;

converting the first gate electrode material into the silicide region (1) comprising the NiSi crystalline phase containing the n-type impurity and the second gate electrode material into the silicide region (2) comprising the NiSi crystalline phase containing the p-type impurity, by carrying out heat treatment to react the first and second gate electrode materials with Ni, as a silicidation step; and

removing the Ni layer being not reacted in the silicidation step.

The present invention further relates to a method for manufacturing the semiconductor device, the method comprising:

preparing a substrate in which the support substrate, the oxide film, and a semiconductor layer with the n-type region and the p-type region are sequentially stacked;

forming a mask pattern on the semiconductor layer;

using the mask pattern as a mask to pattern the semiconductor layer to form the protruding n-type region and the protruding p-type region;

forming the first gate insulating film, a first gate electrode material containing an n-type impurity, and mask (F) in this order on both sides of a central portion of the protruding n-type region;

forming the second gate insulating film, a second gate electrode material containing a p-type impurity, and mask (F) in this order on both sides of a central portion of the protruding p-type region;

forming mask (G) that covers the protruding p-type region, the second gate insulating film, the second gate electrode material, and the mask (F);

using the masks (F) and (G) as a mask to implant a p-type impurity into both portions of the protruding n-type region sandwiching the first gate electrode material to form the source/drain region;

removing the mask (G);

forming mask (H) that covers the protruding n-type region, the first gate insulating film, the first gate electrode material, and the mask (F);

using the masks (F) and (H) as a mask to implant an n-type impurity into both portions of the protruding p-type region sandwiching the second gate electrode material to form the source/drain region;

removing the mask (H);

removing the mask (F);

depositing an Ni layer over the surface;

converting the first gate electrode material into the silicide region (1) comprising the NiSi crystalline phase containing the n-type impurity and the second gate electrode material into the silicide region (2) comprising the NiSi crystalline phase containing the p-type impurity, by carrying out heat treatment to react the first and second gate electrode materials with Ni, as a silicidation step; and

removing the unreacted Ni layer in the silicidation step.

When the semiconductor device of the present invention includes fin-type MOS transistors, the gate insulating films are formed only on the sides of the protruding semiconductor regions (n-type region, p-type region), and channel regions are to be formed only at the sides of the semiconductor regions. In a semiconductor device including planar MOS transistors, the n-type region, the p-type region, and the isolation region form a single plane on the oxide film. However, a slight step may be present between the n-type and p-type regions and the isolation region.

It is possible to provide a semiconductor device that consumes low power and can operate at high speed. Specifically, a MOS transistor with a suppressed short-channel effect and improved mobility can be provided by using an SOI structure to reduce parasitic capacitance and substrate leak current and lowering channel dose in the semiconductor region in which a channel region is to be formed.

Further, using specific materials to form the gate electrodes of the nMOS transistor and the pMOS transistor allows the work functions of the materials that form the gate electrodes to be controlled to desired values. It is therefore possible to provide a semiconductor device with excellent device characteristics in which Vₜₕ values of the nMOS transistor and the pMOS transistor are controlled to be desired values.

### BRIEF DESCRIPTION OF THE DRAWINGS

FIG. 1 shows a related semiconductor device;

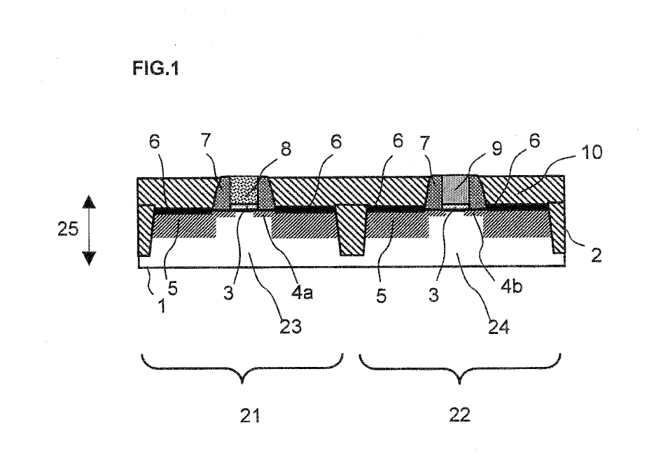

FIG. 2 shows the relationship between the impurity concentration and the threshold voltage (Vₜₕ) in a gate electrode of each of semiconductor devices of related art and the present invention;

FIG. 3 shows the relationship between the impurity concentration and the effective work function in a gate electrode of a related semiconductor device;

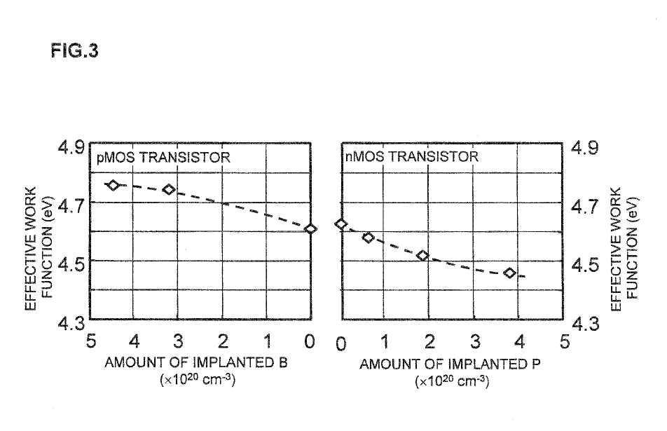

FIG. 4 shows an example of a semiconductor device of the present invention;

FIG. 5 shows an example of a semiconductor device of the present invention;

FIG. 6 shows an example of a method for manufacturing a semiconductor device of the present invention;

FIG. 7 shows an example of a method for manufacturing a semiconductor device of the present invention;

FIG. 8 shows an example of a method for manufacturing a semiconductor device of the present invention;

FIG. 9 shows an example of a method for manufacturing a semiconductor device of the present invention;

FIG. 10 shows an example of a related semiconductor device;

FIG. 11 shows an example of a method for manufacturing a related semiconductor device;

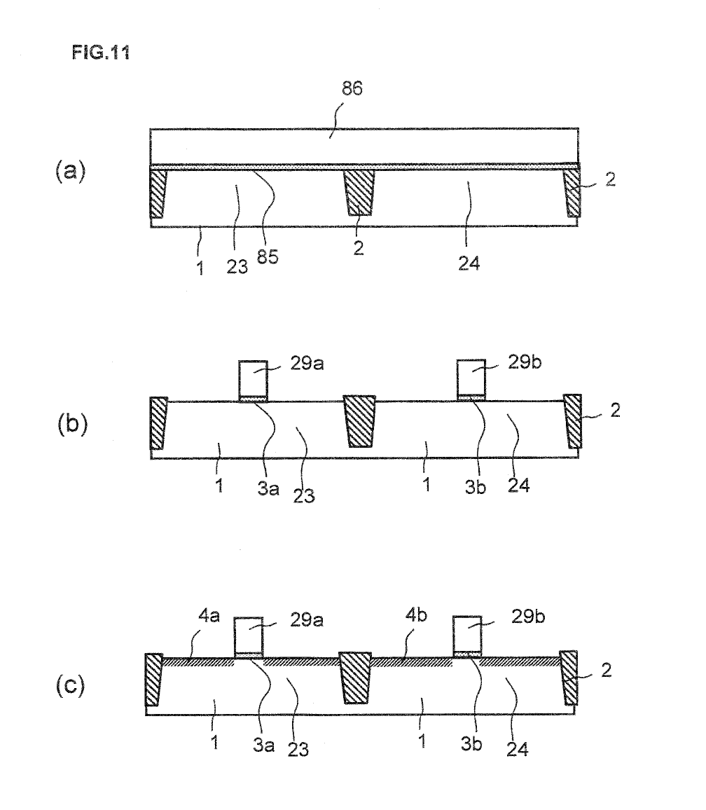

FIG. 12 shows an example of a method for manufacturing a related semiconductor device;

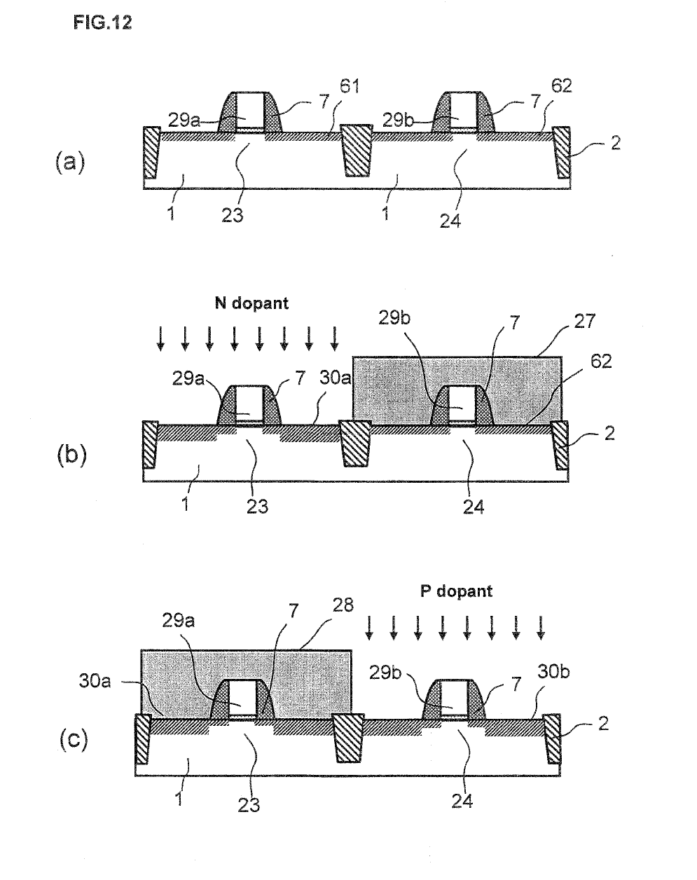

FIG. 13 shows an example of a method for manufacturing a semiconductor device of the present invention;

FIG. 14 shows an example of a method for manufacturing a semiconductor device of the present invention;

FIG. 15 shows an example of a method for manufacturing a semiconductor device of the present invention;

FIG. 16 shows an example of a method for manufacturing a semiconductor device of the present invention;

FIG. 17 shows an example of a method for manufacturing a semiconductor device of the present invention;

FIG. 18 shows an example of a method for manufacturing a semiconductor device of the present invention;

FIG. 19 shows an example of a method for manufacturing a semiconductor device of the present invention;

FIG. 20 shows an example of a method for manufacturing a semiconductor device of the present invention; and

FIG. 21 shows an example of a method for manufacturing a semiconductor device of the present invention.

In the drawings, numerals have the following meanings.

1: Si substrate, 2: isolation region, 3, 3a, 3b: gate insulating film, 4a, 4b: extension diffusion region, 5: source/drain region, 6, 32: silicide layer, 7: gate sidewall, 8: n-type impurity-doped Ni silicide electrode, 9: p-type impurity-doped Ni silicide electrode, 9a: second gate electrode, 9b, first gate electrode, 10: interlayer insulating film, 11: embedded oxide film, 14a, 29a: second gate electrode material, 14b, 29b: first gate electrode material, 15: mask, 21: nMOS transistor, 22: pMOS transistor, 23: p-type region, 24: n-type region, 27, 28: mask, 30a: n-type source/drain region, MD: p-type source/drain region, 41, 42, 43, 44, 45: mask, 51, 80: Ni layer, 55: semiconductor layer, 56: mask, 61, 62: extension region, 63a, 63b: polysilicon layer, 64a, 64b, 65, 66, 67a, 67b, 68a, 68b: mask, 85: insulating film layer, 86: polysilicon layer.

### BEST MODE FOR CARRYING OUT THE INVENTION

### Semiconductor Device

A semiconductor device of the present invention includes an nMOS transistor and a pMOS transistor. Each of the nMOS and pMOS transistors is formed by using an SOI substrate, and forms a fully depleted MOS transistor. In the semiconductor device of the present invention, the MOS transistors may be planar MOS transistors or fin-type MOS transistors. Alternatively, the semiconductor device may include both a planar MOS transistor and a fin-type MOS transistor.

The semiconductor device of the present invention is used as a low-power device (conducting small off-leak current). Specifically, for example, the power consumption of the semiconductor device is reduced by 30% and the performance is improved (the semiconductor device is operated at higher speeds) by 30% as compared to a MOS device in which a channel region is made of partially depleted bulk silicon.

The pMOS transistor and the nMOS transistor of the present invention may form a CMOS transistor.

The semiconductor device of the present invention is characterized in that first and second gate electrodes include silicide regions, each of which is made of a silicide material having a specific composition containing a specific impurity element. Examples of the impurity elements are a p-type impurity for the second gate electrode of the nMOS transistor and an n-type impurity for the first gate electrode of the pMOS transistor.

Use of such impurity elements has not been contemplated at all in the related art because of the reasons described in (1) to (3). Further, the related art has not produced any knowledge about the relationship between the material that forms a metal gate electrode and Vₜₕ in a fully depleted MOS transistor using an SOI substrate from the viewpoint of a low-power device.

The present invention is characterized in that the first gate electrode of the pMOS transistor includes silicide region (1) containing an n-type impurity and the second gate electrode of the nMOS transistor includes silicide region (2) containing a p-type impurity. The thus configured gate electrodes allow the work functions of the materials that form the first and second gate electrodes to be controlled to be predetermined values and hence Vₜₕ (threshold voltage) values to be controlled to be predetermined values necessary for low-power MOS transistors. As a result, a semiconductor device with excellent device characteristics can be provided.

### First Exemplary Embodiment

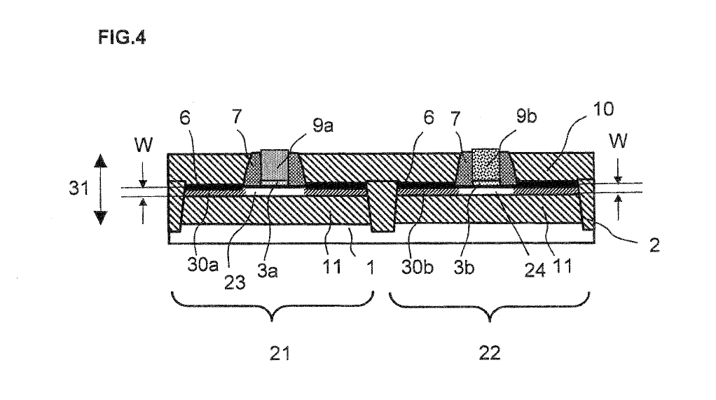

FIG. 4 shows an example of a semiconductor device of the present invention. FIG. 4 shows the semiconductor device with planar MOS transistors. The semiconductor device is formed by using an SOI substrate including support substrate 1, embedded oxide film 11, and a semiconductor layer. P-type region 23 and n-type region 24 are formed in the semiconductor layer.

Second gate insulating film 3a and second gate electrode 9a are formed on part of p-type region 23. Gate sidewall 7 is formed on the side of second gate electrode 9a. Second gate electrode 9a includes a p-type impurity-containing Ni silicide region (silicide region (2)) in contact with second gate insulating film 3a.

Further, n-type source/drain region 30a is formed on both sides of p-type region 23 sandwiching second gate electrode 9a. Source/drain region 30a is formed throughout p-type region 23 along the direction of a normal to the surface where the p-type region is in contact with the second gate insulating film (the direction of a normal to embedded oxide film 11, the direction indicated by reference numeral 31 in FIG. 4). Silicide layer 6 is formed on n-type source/drain region 30a. P-type region 23, second gate insulating film 3a, second gate electrode 9a, and n-type source/drain region 30a form nMOS transistor 21.

Similarly, first gate insulating film 3b and first gate electrode 9b are formed on part of n-type region 24, and gate sidewall 7 is formed on the side of first gate electrode 9b. P-type source/drain region 30b is formed on both sides of n-type region 24 sandwiching first gate electrode 9b. Source/drain region 30b is formed throughout n-type region 24 along the direction of a normal to the surface where the n-type region is in contact with the first gate insulating film (the direction of a normal to embedded oxide film 11, the direction indicated by reference numeral 31 in FIG. 4). First gate electrode 9b includes an n-type impurity-containing Ni silicide region (silicide region (1)) in contact with first gate insulating film 3b. N-type region 24, first gate insulating film 3b, first gate electrode 9b, and p-type source/drain region 30b form pMOS transistor 22.

The thickness (the length in the direction indicated by reference numeral 31) W of p-type region 23 and n-type region 24 is thin. Therefore, when each of the MOS transistors is in operation, the body region is fully depleted. The thickness W of p-type region 23 and n-type region 24 (the length of p-type region 23 and n-type region 24 in the direction of a normal to the surfaces where p-type region 23 and n-type region 24 are in contact with the second and first gate insulating films, respectively) preferably ranges from 5 to 20 nm, more preferably 5 to 10 nm, still more preferably 5 to 10 nm.

In the semiconductor device, since each of p-type region 23 and n-type region 24 is thin, it is not possible to form an extension region separately from the source/drain region by controlling impurity implantation conditions. Therefore, each of the MOS transistors includes no extension region, and the entire active portion on both sides of the gate electrode and the gate sidewall is the source/drain region. That is, the source/drain region is present all along the thickness direction 31 so that the source/drain region is in contact with both silicide 6 and embedded oxide film 11.

Second gate electrode 9a and first gate electrode 9b may be connected to each other or may be separated. When they are connected to each other, it is necessary to form the gate electrodes (silicidation) in such a way that of one of the gate electrode material will not diffuse into the other gate electrode material so as not to cause shift in composition of both the gate electrode materials from desired composition.

### Second Exemplary Embodiment

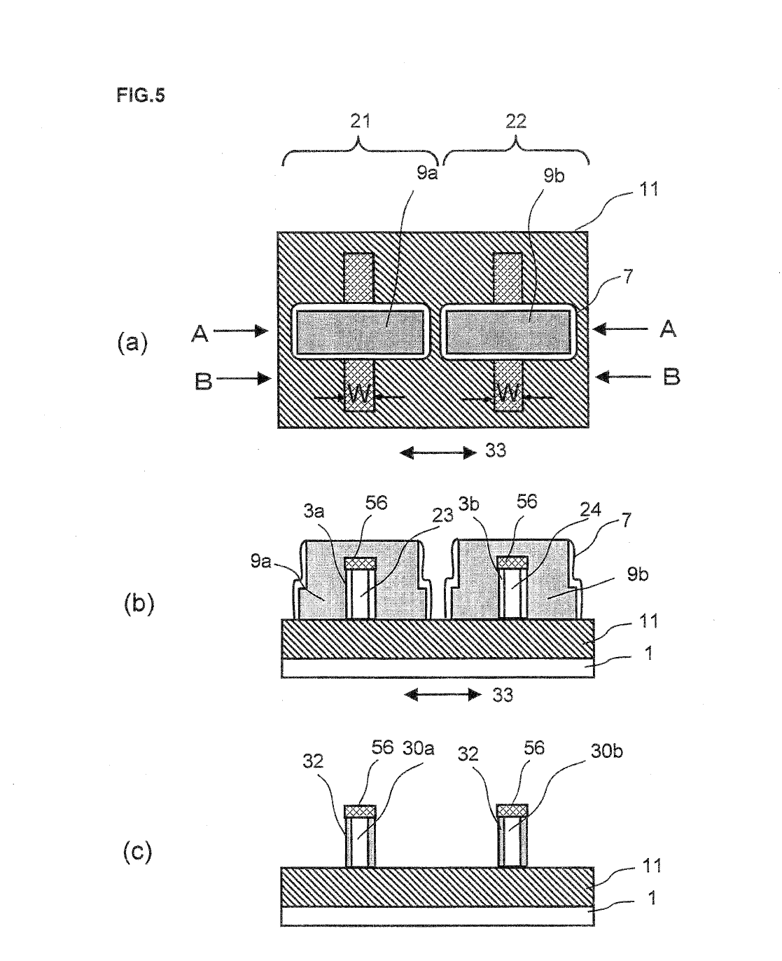

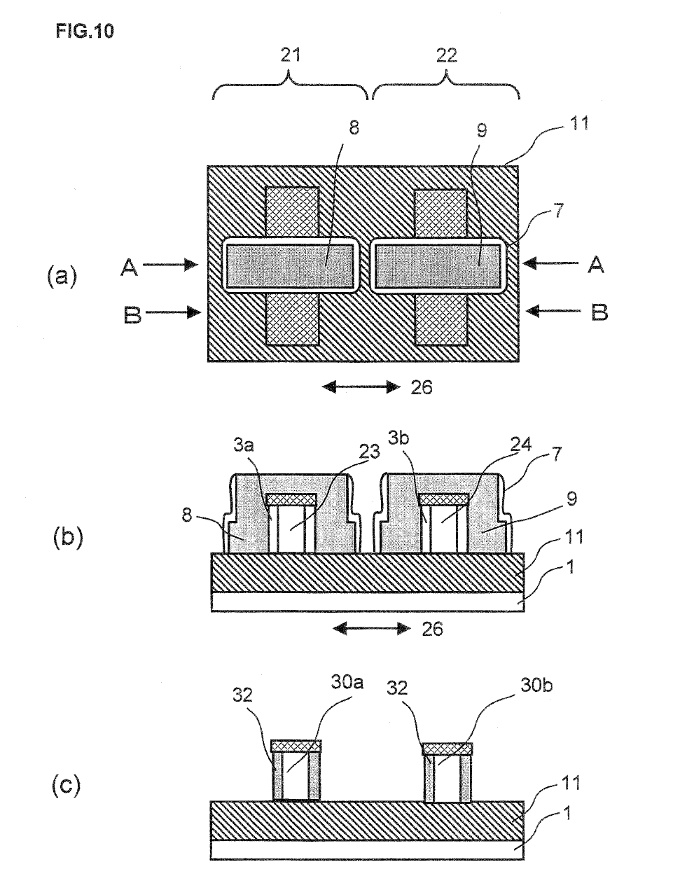

FIG. 5 shows another example of the semiconductor device of the present invention. FIG. 5(a) is a top view of the semiconductor device. FIG. 5(b) is a cross-sectional view of the semiconductor device in FIG. 5(a) taken along line A-A. FIG. 5(c) is a cross-sectional view of the semiconductor device in FIG. 5(a) taken along line B-B. The semiconductor device differs from the semiconductor device shown in FIG. 10 in that the width W (the length in the direction indicated by reference numeral 33) of p-type region 23 and n-type region 24 is narrower, each of the MOS transistors is fully depleted, and each of the gate electrodes includes an Ni silicide region containing a specific impurity element.

The semiconductor device is formed by using an SOI substrate including support substrate 1, embedded oxide film 11, and a semiconductor layer. P-type region 23 and n-type region 24 are formed on embedded oxide film 11 such that they protrude and they form protruding semiconductor regions. The shape of the protruding semiconductor region is not limited to a specific one as long as there are both sides. Typical examples of the shape may include a box-like shape and a substantially box-like shape. Second gate electrode 9a and first gate electrode 9b are formed on both sides of p-type region 23 and n-type region 24, respectively. Second gate insulating film 3a is formed between the side of p-type region 23 and second gate electrode 9a, and first gate insulating film 3b is formed between the side of n-type region 24 and first gate electrode 9b.

Second gate electrode 9a includes p-type impurity-containing NiSi silicide region (2) in contact with second gate insulating film 3a. First gate electrode 9b includes n-type impurity-containing NiSi silicide region (1) in contact with first gate insulating film 3b. Gate sidewalls 7 are formed on the sides of second gate electrode 9a and first gate electrode 9b.

Insulating film layers 56 are formed between the upper surface of p-type region 23 and second gate electrode 9a and between the upper surface of n-type region 24 and first gate electrode 9b. An example of insulating film layer 56 may be a silicon nitride film.

Both sides of n-type region 24 sandwiching first gate electrode 9b and both sides of p-type region 23 sandwiching second gate electrode 9a form p-type source/drain region 30b and n-type source/drain region 30a, respectively. Insulating film layers 56 extend from the upper sides of p-type region 23 and n-type region 24 along the upper sides of n-type source/drain region 30a and p-type source/drain region 30b. Silicide layers 32 are formed on the sides of n-type source/drain region 30a and p-type source/drain region 30b.

In the present exemplary embodiment, p-type region 23, second gate insulating film 3a, source/drain region 30a, and second gate electrode 9a form nMOS transistor 21. N-type region 24, first gate insulating film 3b, source/drain region 30b, and first gate electrode 9b form pMOS transistor 22.

When the MOS transistors are in operation, the body region in the portion of p-type region 23 immediately under second gate electrode 9a (both sides of p-type region 23) is fully depleted, and the body region in the portion of n-type region 24 immediately under first gate electrode 9b (both sides of n-type region 24) is fully depleted. The entire both portions of p-type region 23 sandwiching the second gate electrode and the entire both portions of n-type region 24 sandwiching the first gate electrode form source/drain regions 30a and 30b, respectively.

In the MOS transistors of the present exemplary embodiment, the gate electrodes are formed only on the sides of the n-type region and the p-type region via the gate insulating films. Channel regions are therefore to be formed on the sides of p-type region 23 and n-type region 24.

The thickness W of p-type region 23 and n-type region 24 (the length of p-type region 23 and n-type region 24 in the direction of a normal to the surfaces where p-type region 23 and n-type region 24 are in contact with the second and first gate insulating films, the length in the direction indicated by reference numeral 33) preferably ranges from 5 to 20 nm, more preferably 5 to 10 nm, still more preferably 5 to 7 nm so that the MOS transistors are fully is depleted during operation.

First gate electrode 9b and second gate electrode 9a may be connected to each other or may be separated. When they are connected to each other, it is necessary to form the gate electrodes (silicidation) in such a way that one of the gate electrode materials will not diffuse into the other gate electrode material so as not to cause shift in composition of both the gate electrode materials from desired composition.

(Full Depletion)

Whether a semiconductor device is fully depleted or partially depleted depends on the relationship of film thickness L1 (the width W in the direction indicated by reference numeral 31 in FIG. 4, the width W in the direction indicated by reference numeral 33 in FIG. 5) of the semiconductor layer (n-type region, p-type region) in which the channel region is formed with maximum depletion layer width L2. That is, when film thickness L1 of the semiconductor layer is smaller than maximum depletion layer width L2, the semiconductor device becomes partially depleted, whereas film thickness L1 of the semiconductor region is greater than maximum depletion layer width L2, the semiconductor device becomes fully depleted.

In a planar MOS transistor, film thickness L1 refers to the thickness in the thickness direction (the direction of a normal to the substrate, the length of p-type region 23 in the direction of a normal to the surface where p-type region 23 is in contact with the second gate insulating film, the length of n-type region 24 in the direction of a normal to the surface where n-type region 24 is in contact with the first gate insulating film). In a fin-type MOS transistor, film thickness L1 refers to the length in the direction of a normal to the gate electrode (the length of p-type region 23 in the direction of a normal to the surface where p-type region 23 is in contact with the second gate insulating film, the length of n-type region 24 in the direction of a normal to the surface where n-type region 24 is in contact with the first gate insulating film, the length in the direction parallel to the embedded oxide film but perpendicular to the direction of the gate length, the length in the direction parallel to the embedded oxide film but perpendicular to the direction of the channel length).

Maximum depletion layer width L2 is given by the following equations (1) and (2):

L2=(2∈_{Si}∈₀2φ_{F}/qN_{A})^{1/2} (1)

φ_{F}=(kT/q)ln(N_{A}/nᵢ) (2)

(In the equations, ∈_{Si}: relative dielectric constant of silicon, ∈₀: dielectric constant in vacuum, q: elementary electric charge, N_{A}: impurity concentration in the semiconductor region, k: Boltzmann constant, T: temperature, nᵢ: intrinsic carrier concentration)

Therefore, to form a MOS transistor to be fully depleted, film thickness L1 of the semiconductor layer and impurity concentration N_{A} may be controlled. In a semiconductor device of the present invention, however, to suppress the short-channel effect and improve the mobility at a low power level, it is necessary to set the impurity concentration in the channel region to a low value (typically, the impurity concentration ranges from 1×10¹⁴ to 1×10¹⁷ cm⁻³).

In the present invention, N_{A} in equations (1) and (2) is therefore set to a low concentration value, and maximum depletion layer width L2 is set to a value within a predetermined range accordingly. A MOS transistor can therefore be fully depleted by controlling film thickness L1 of the semiconductor region.

Further, in such a fully depleted MOSFET, using an SOI structure, that is, making the silicon layer on the oxide film thin can suppress the short-channel effect. As a result, the short-channel effect in a miniature transistor can be suppressed in a low-channel-concentration area, which has been difficult in a bulk-type (partially depleted) MOSFET, whereby device characteristics can be greatly improved.

Typically, a fully depleted MOS transistor can be reliably achieved when the following conditions are satisfied:

(a) The length of the n-type region in the direction of a normal to the surface where the n-type region is in contact with the first gate insulating film is one-fourth of the gate length of the pMOS transistor or smaller.
(b) The length of the p-type region in the direction of a normal to the surface where the p-type region is in contact with the second gate insulating film is one-fourth of the gate length of the nMOS transistor or smaller.

Typical dimensions of each MOS transistor (planar MOS transistor, fin-type MOS transistor) that forms a semiconductor device of the present invention are shown as follows:

### (Planar MOs Transistor)

Gate length: 10 to 50 nm

Thickness of gate insulating film: 1 to 5 nm (for SiO₂)

### (Fin-Type MOs Transistor)

Height H of protruding n-type region and protruding p-type region: 20 to 200 nm

Gate length: 10 to 50 nm

Thickness of gate insulating film: 1 to 5 nm (for SiO₂)

The following sections describe materials of each component of a semiconductor device of the present invention shown in the above first and second exemplary embodiments by way of example.

(Gate Insulating Film)

The gate insulating film preferably does not contain oxides or nitrides of a metal, such as Hf and Zr, or mixtures of metal oxides or nitrides and silicon oxides in order to prevent Fermi level pinning from occurring at the interface between the gate electrode and the gate insulating film, because when Fermi level pinning occurs at the interface between the gate electrode and the gate insulating film, modulation of the effective work function due to impurities in the gate electrode will not occur. Specifically, a silicon oxide film (SiO₂), a silicon oxynitride film (SiON), or a silicon nitride film (SiN) is preferably used as the first and second insulating films. A silicon oxynitride film (SiON) is more preferable from the viewpoint of preventing impurities from penetrating from poly-Si into the channel region before the gate electrode is fully converted into silicide (NiSi) and ensuring long-term reliability of the gate insulating film.

(Gate Electrode)

The first gate electrode that forms part of a semiconductor device of the present invention includes an n-type impurity-containing Ni silicide region (silicide region (1)) in contact with the first gate insulating film. The n-type impurity-containing Ni silicide region (silicide region (1)) may form part or entire of the first gate electrode as long as the first gate electrode includes an n-type impurity-containing Ni silicide region (silicide region (1)) in contact with the first gate insulating film. An NiSi crystalline phase containing an n-type impurity is present as a primary crystalline phase in silicide region (1). Another region may be further formed on the n-type impurity-containing Ni silicide region.

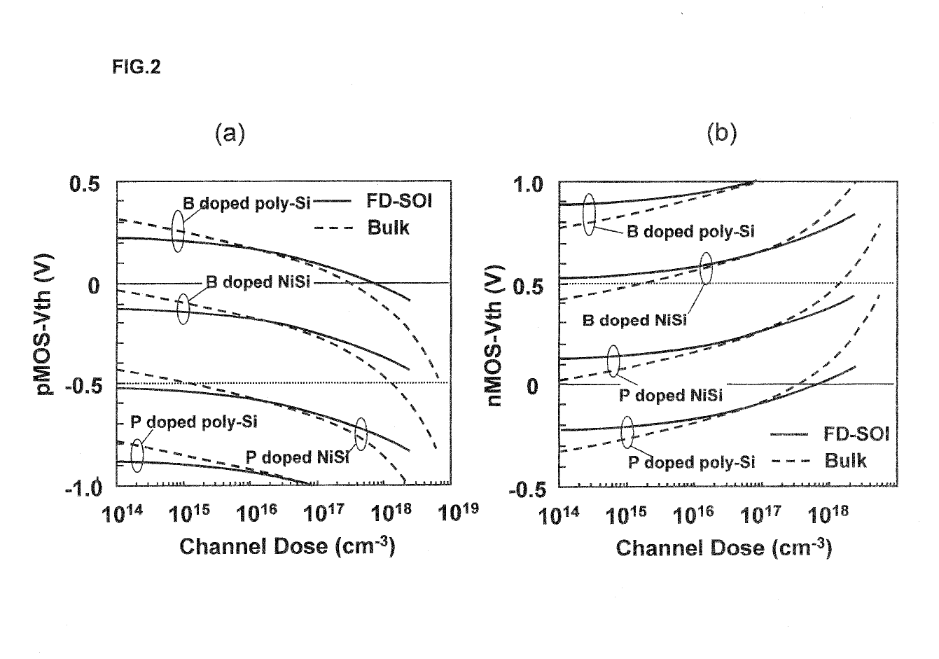

The n-type impurity is preferably at least one type of impurity element selected from the group consisting of P, As, and Sb. Any of P, As, and Sb is implanted into the first gate electrode to control the work function of the first gate electrode, whereby Vₜₕ can be readily controlled to be a value within the range (from −0.6 to −0.3 V) necessary for a low-power pMOS transistor. For example, FIG. 2(a) shows that when the gate electrode comprises an NiSi crystalline phase containing P as the n-type impurity, Vₜₕ can be set to a value within the range from −0.6 to −0.3 V in the low-channel-dose area.

The concentration of the n-type impurity in the Ni silicide region (silicide region (1)) (when a plurality of n-type impurities are present, the concentration values of all the n-type impurities) preferably ranges from 2×10²⁰ to 1×10²¹ cm⁻³, more preferably 5×10²⁰ to 1×10²¹ cm⁻³. When the concentration of the n-type impurity varies in silicide region (1), the average concentration of the n-type impurity in silicide region (1) preferably falls within any of the ranges described above. The Vₜₕ value of the pMOS transistor can be effectively controlled by ensuring that the concentration of the n-type impurity in the first gate electrode falls within any of the above ranges.

The second gate electrode that forms part of a semiconductor device of the present invention includes a p-type impurity-containing Ni silicide region (silicide region (2)) in contact with the second gate insulating film. Ni silicide region (2) may form part or entire of the second gate electrode as long as the second gate electrode includes p-type impurity-containing Ni silicide region (2) in contact with the second gate insulating film. An NiSi crystalline phase containing a p-type impurity is present as a primary crystalline phase in silicide region (2). Another region may be further formed on Ni silicide region (2).

The p-type impurity is preferably B. The impurity element is implanted into the second gate electrode to control the work function thereof, whereby Vₜₕ can be readily controlled to be a value within the range (from 0.3 to 0.6 V) necessary for a low-power nMOS transistor. For example, FIG. 2(b) shows that when the gate electrode comprises an NiSi crystalline phase containing B as the p-type impurity, Vₜₕ can be set to a value within the range from 0.3 to 0.6 V in the low-channel-dose area.

The concentration of the p-type impurity in the Ni silicide region (silicide region (2)) (when a plurality of p-type impurities are present, the concentration values of all the p-type impurities) preferably ranges from 2×10²⁰ to 1×10²¹ cm⁻³, more preferably 5×10²⁰ to 1×10²¹ cm⁻³. When the concentration of the p-type impurity varies in silicide region (2), the average concentration of the p-type impurity in silicide region (2) preferably falls within any of the ranges described above. The Vₜₕ value of the nMOS transistor can be effectively controlled by ensuring that the concentration of the p-type impurity in the second gate electrode falls within any of the above ranges.

The composition of the Ni silicide in the silicide regions containing the n-type impurity and the p-type impurity (silicide regions (1) and (2)) can be selected from a relatively wide range when the gate insulating film is a silicon oxide film or a silicon oxynitride film (SiON) and has a composition dose to NiSi. This reason is that the effective work function of an Ni silicide electrode substantially remains unchanged on a gate insulating film made of SiO₂ or SiON irrespective of the composition ratio of the Ni silicide electrode, and the effective work function changes primarily depending on the type and the amount of the impurity contained in silicide regions (1) and (2). It is however preferable that the composition of the Ni silicide in silicide region (1) is the same as that in silicide region (2). A typical composition ratio of the Ni silicide is NiₓSi₁₋ₓ (0.45≦x≦0.55).

(Active Region)

The n-type region (n-type active region: n-well) and the p-type region (p-type active region: p-well) that form a semiconductor device of the present invention contain n-type and p-type impurity elements, respectively. To operate a MOS transistor at a higher speed, improve the drive rate, and reduce power consumption, it is necessary to lower the n-type impurity concentration in the n-type region and the p-type impurity concentration in the p-type region.

The impurity concentration typically ranges from 1×10¹⁴ to 1×10¹⁷ cm⁻³, preferably 1×10¹⁴ to 1×10¹⁶ cm⁻³, more preferably 1×10¹⁴ to 1×10¹⁵ cm⁻³.

(Source/Drain Region)

An n-type impurity element is implanted into the source/drain region of an nMOS transistor, and a p-type impurity element is implanted into the source/drain region of a pMOS transistor. The n-type impurity element may be P, As, and Sb, and the p-type impurity element may be B or other elements. The impurity element concentration in the source/drain region typically ranges from 1×10¹⁹ to 1×10²¹ cm⁻³.

Further, a silicide layer may be formed on the source/drain region of each MOS transistor. The material that forms the silicide layer is not particularly limited, but may be Ni silicide, Co silicide, Ti silicide, and other metal silicides. It is preferable to use a silicide material that is not altered during the formation of the gate electrode (annealing for converting the entire gate electrode into silicide) but is stable at high temperatures.

(Method for Manufacturing Semiconductor Device)

### First Exemplary Embodiment

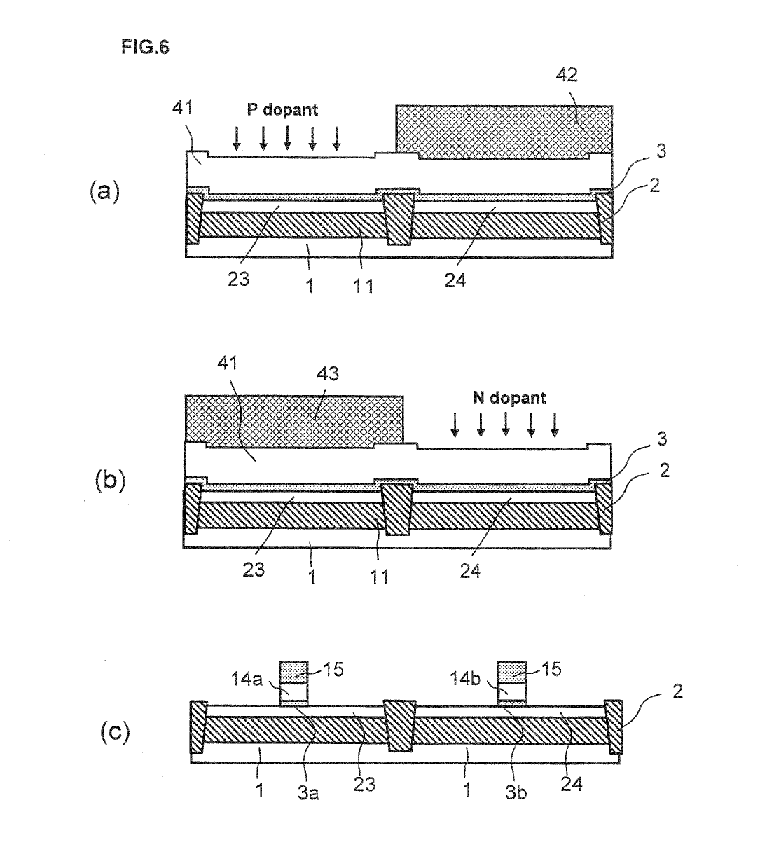

FIGS. 6 to 9 show an example of a method for manufacturing a semiconductor device of the present invention. FIGS. 6 to 9 show a method for manufacturing a semiconductor device in which each of an nMOS transistor and a pMOS transistor form a planar transistor.

First, an SOI substrate including support substrate 1, embedded oxide film 11, and a silicon layer with n-type region 24 and p-type region 23 is prepared. The thickness of the silicon layer in the SOI substrate is adjusted in such a way that manufactured MOS transistors are fully depleted. The SOI substrate can be formed by using bonding or SIMOX. For example, a smart-cut method or an ELTRAN method may be used.

STI (Shallow Trench Isolation) technique is then used to form isolation region 2 in the silicon layer so that n-type region 24 and p-type region 23 are isolated.

Thermal oxidation is subsequently used to form insulating film 3 comprising a silicon oxynitride film on the surface of the silicon layer. Insulating film 3 may be alternatively comprising a silicon oxide film or a silicon nitride film. Poly-Si film (polysilicon film) 41 is then deposited on insulating film 3 by using CVD (Chemical Vapor Deposition).

Mask (A) 42 is then formed on polysilicon film 41 formed on n-type region 24. A hard mask comprising an insulating film can be used as mask (A) 42. Mask (A) 42 is used as a mask to implant a p-type impurity element into polysilicon film 41 formed on p-type region 23. As the p-type impurity element, B can be implanted (FIG. 6(a)). The implantation of B is preferably carried out by using ion implantation under the condition of 2 keV and an implantation angle of zero degrees.

After mask (A) 42 is removed, mask (B) 43 is formed on polysilicon film 41 formed on p-type region 23. Mask (B) 43 is used as a mask to implant an n-type impurity element into polysilicon film 41 formed on n-type region 24. As the n-type impurity element, at least one type of impurity element selected from the group consisting of P, As, and Sb can be implanted (FIG. 6(b)). The implantation of any of the impurity elements is preferably carried out by using ion implantation under the condition of 5 keV and an implantation angle of zero degrees.

After a mask layer is deposited over the resulting surface, patterning is carried out by using lithography technique and reactive ion etching (RIE) technique. The patterning forms a region comprising gate insulating film 3a, second gate electrode material 14a, and mask (C) 15 on p-type region 23, and a region comprising gate insulating film 3b, second gate electrode material 14b, and mask (C) 15 on n-type region 24 (FIG. 6(c)).

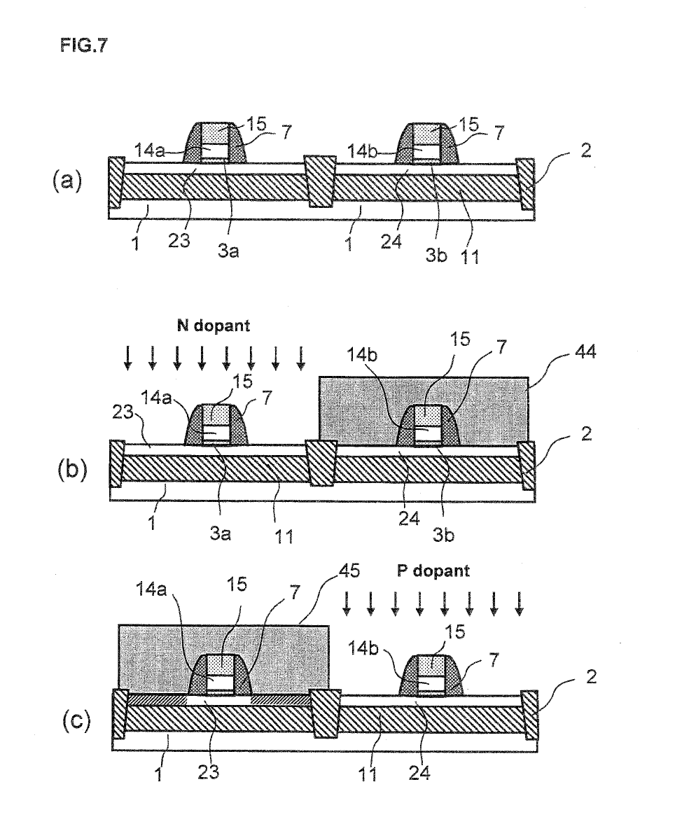

After a silicon oxide film is further deposited, the resulting structure is etched back to form gate sidewalls 7 on the sides of first gate insulating film 3b, first gate electrode material 14b, and mask (C) 15 and the sides of second gate insulating film 3a, second gate electrode material 14a, and mask (C) 15 (FIG. 7(a)).

After mask (D) 44 is formed over n-type region 24, masks (C) and (D) and the gate sidewall are used as a mask to implant an n-type impurity into p-type region 23 (FIG. 7(b)). After mask (D) 44 is removed, mask (E) 45 is formed on the p-type region. Masks (C) and (E) and gate sidewall 7 are used as a mask to implant a p-type impurity into n-type region 24 (FIG. 7(c)). Mask (E) 45 is then removed.

Annealing is then carried out to activate the n-type impurity in p-type region 23 and the p-type impurity in n-type region 24 so as to form n-type source/drain region 30a in p-type region 23 and p-type source/drain region 30b in n-type region 24. Mask (C), the gate sidewalls, and the STI are used as a mask in conjunction with salicide technique to form silicide layers 6 only on source/drain regions 30a and 30b.

Silicide layer 6 is made of Ni mono-silicide (NiSi), by which contact resistance can be minimized. The silicide layer may be made of any other heat-resistant silicide that is not altered when the first and second gate electrode materials undergo silicidation. Specifically, Ni silicide may be replaced with Co silicide or Ti silicide.

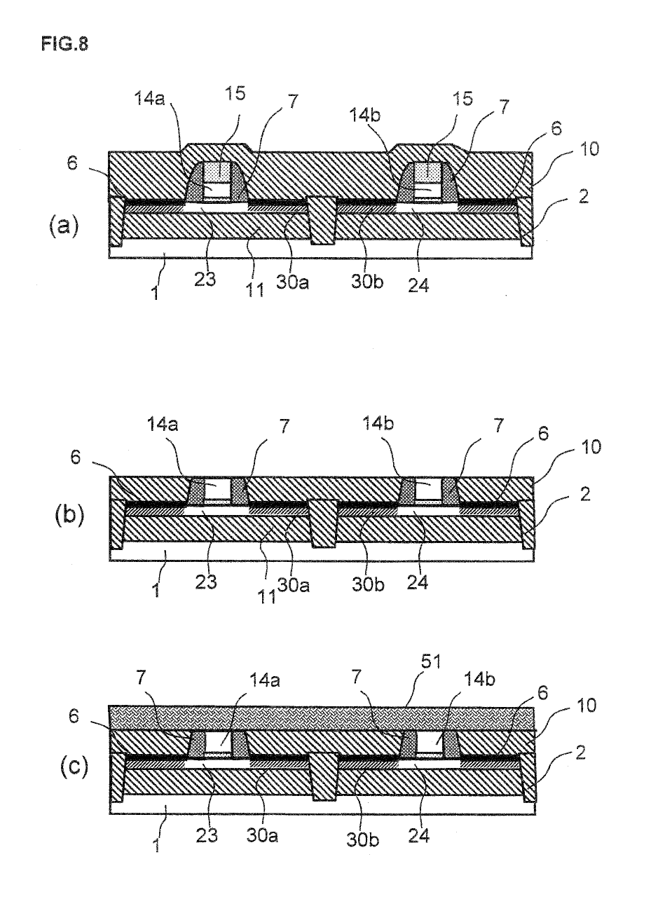

Further, CVD (Chemical Vapor Deposition) is used to form interlayer insulating film 10 comprising a silicon oxide film (FIG. 8(a)). CMP technique is then used to planarize interlayer insulating film 21 to expose mask (C) 15. Mask (C) 15 is removed to expose first and second gate electrode materials 14a and 14b (FIG. 8(b)). CVD or any other similar method is then used to deposit Ni film 51 over the resulting surface (FIG. 8(c)).

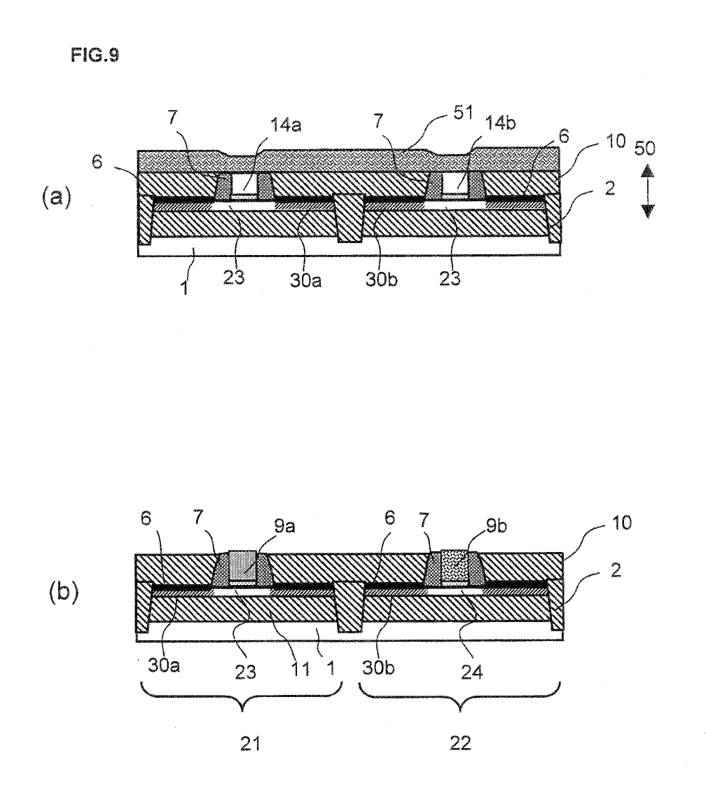

Heat treatment is then carried out to react Ni with the first and second gate electrode materials so that the first and second gate electrode materials are converted into silicide. The first gate electrode material is converted into silicide region (1) comprising an NiSi crystalline phase containing the n-type impurity and the second gate electrode material is converted into silicide region (2) comprising an NiSi crystalline phase containing the p-type impurity (silicidation). FIG. 9(a) shows a step in the middle of the silicidation.

The heat treatment needs to be carried out in a non-oxidation atmosphere in order to prevent oxidation of the metal film. While a variety of Ni silicides (Ni₂Si, NiSi₂, and Ni₃Si) are known as Ni silicide, the silicidation conditions are set in such a way that an NiSi crystalline phase is formed. That is, the composition of the Ni silicide obtained in the Ni silicidation changes depending on the film thickness of the Ni layer deposited on the polysilicon and the silicidation temperature. In the present exemplary embodiment, silicidation in which an NiSi crystalline phase is selectively achieved can be carried out by selecting the film thickness of the Ni layer and the silicidation temperature at which an NiSi crystalline phase is formed.

Specific conditions for obtaining an NiSi crystalline phase may be, for example, the silicidation temperature ranging from 350 to 400° C., the ratio of the height (the length in the direction indicated by reference numeral 50) of the first and second gate electrode materials to the thickness of the Ni layer (T_{Ni}/T_{Si}) ranging from 0.6 to 0.8, and the period of heat treatment ranging from 60 to 300 seconds.

The excess Ni film that has not reacted in the silicidation step described above is removed in a wet etching process using sulfuric acid in a hydrogen peroxide solution (FIG. 9(b)).

### Second Exemplary Embodiment

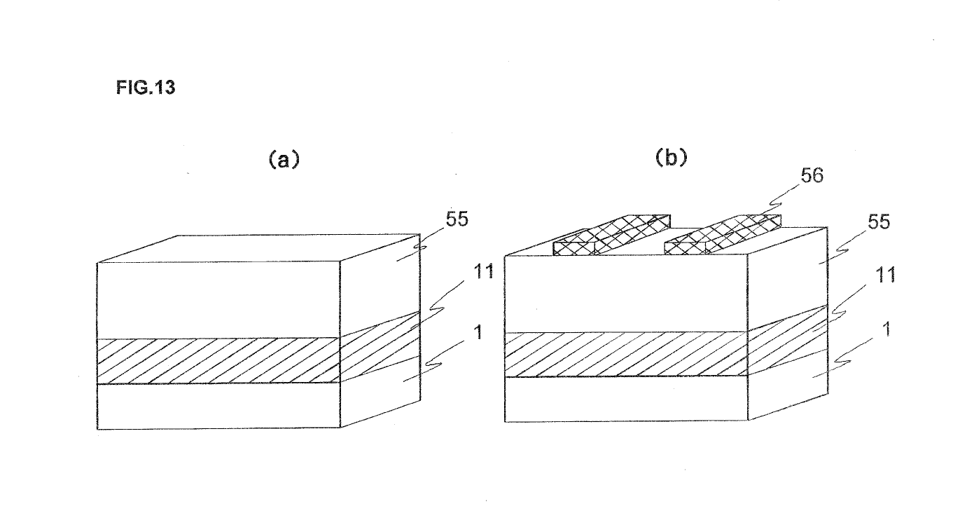

FIGS. 13 to 20 explain another example of the method for manufacturing a semiconductor device of the present invention. The manufacturing method relates to a method for manufacturing a semiconductor device including a fin-type MOSFET. First, a substrate with silicon substrate 1, embedded oxide film 11, and silicon semiconductor layer 55 with n-type and p-type regions sequentially stacked is prepared: (FIG. 13(a)).

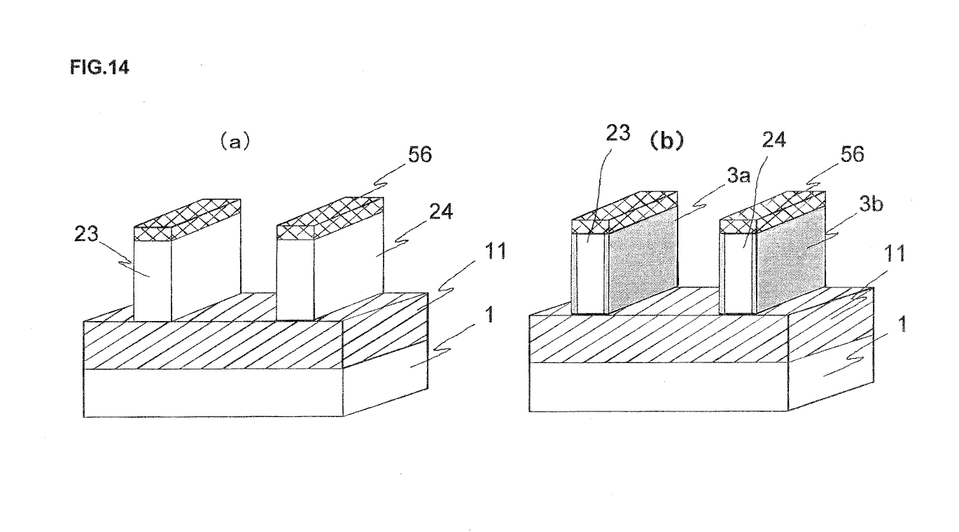

Mask pattern 56 is then formed on silicon semiconductor layer 55 (FIG. 13(b)). A silicon oxide film or a silicon nitride film can be used as mask pattern 56, a silicon nitride film is preferably used. Mask pattern 56 is then used as a mask to etch the resulting structure so as to form protruding p-type region 23 and n-type region 24 protruding from embedded oxide film 11 (FIG. 14(a)).

Thermal oxidation is carried out on p-type region 23 and n-type region 24 to form second gate insulating film 3a and first gate insulating film 3b (SiO₂ film) on both sides of protruding p-type region 23 and n-type region 24, respectively (FIG. 14(b)).

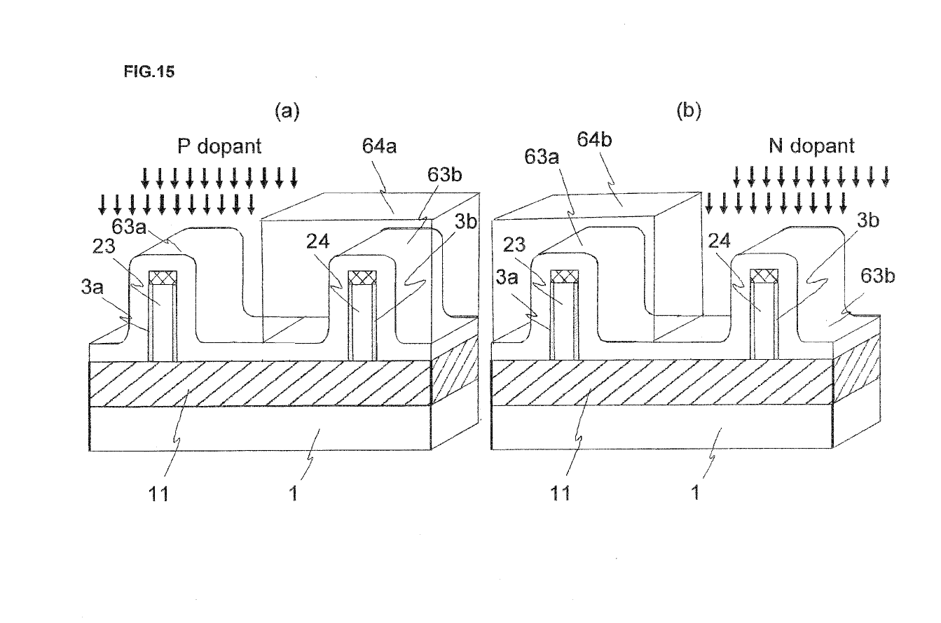

Polysilicon layers 63a and 63b are then formed to cover respective protruding p-type region 23 and n-type region 24 from one side thereof through the upper surface to the other side. Lithography is then used to form resist mask 64a on polysilicon layer 63b that covers n-type region 24, and a p-type impurity is implanted into polysilicon layer 63a (FIG. 15(a)). After mask 64a is removed, lithography is used to form resist mask 64b on polysilicon layer 63a that covers p-type region 23, and an n-type impurity is implanted into polysilicon layer 63b (FIG. 15(b)).

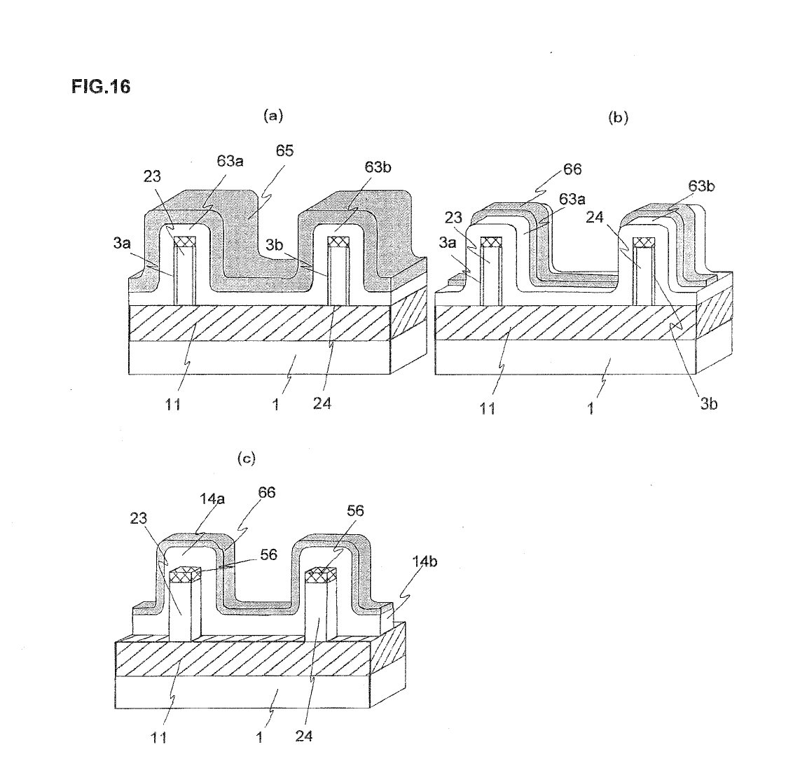

After resist mask 64b is removed, mask layer 65 is formed to cover polysilicon layers 63a and 63b (FIG. 16(a)). A silicon oxide film or a silicon nitride film can be used as mask layer 65, a silicon nitride film is preferably used. Lithography is then used to form a gate electrode pattern on mask layer 65, and mask layer 65 is dry etched into the shape of the gate electrode pattern (mask (F)) 66 (FIG. 16(b)).

Mask (F) 66 that has been shaped into the gate electrode pattern is used as a mask to dry etch the resulting structure so as to form first gate electrode material 14b that straddles the central part of n-type region 24 and second gate electrode material 14a that straddles the central part of p-type region 23 (FIG. 16(c)). At the same time in this process, sides of both portions of p-type region 23 sandwiching second gate electrode material 14a and sides of both portions of n-type region 24 sandwiching first gate electrode material 14b are exposed. In this process, mask 56 prevents decrease in height of protruding p-type region 23 and n-type region 24 due to over-etching.

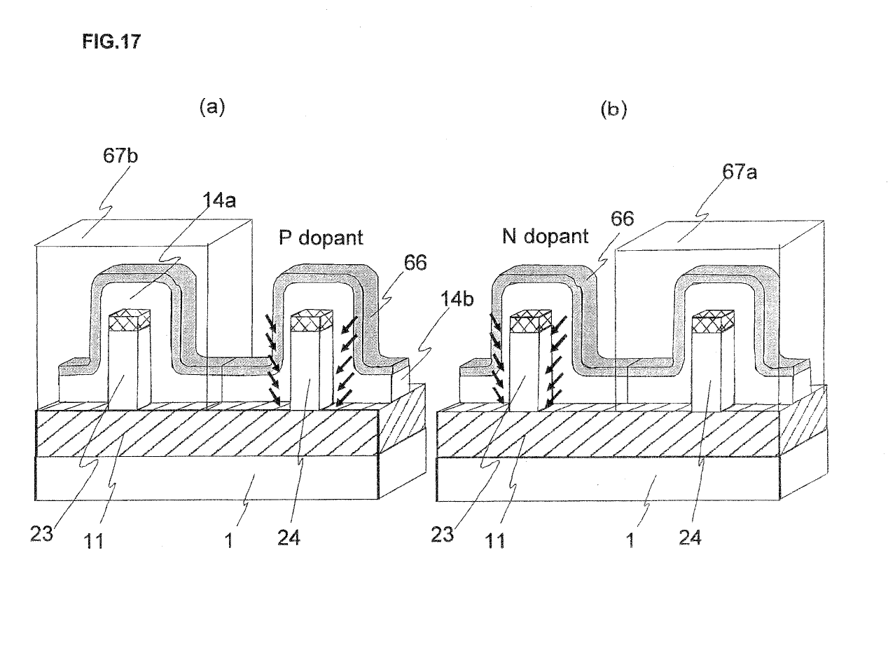

Lithography is then used to form mask 67b that covers p-type region 23, second gate electrode material 14a, and mask (F) 66. Mask 67b and mask (F) 66 are then used as a mask to obliquely implant a p-type impurity into the side of n-type region 24 so as to form an extension region in n-type region 24 (FIG. 17(a)). After mask 67b is removed, lithography is used to form mask 67a that covers n-type region 24, first gate electrode material 14b, and mask 66. Mask 67a and mask (F) 66 are then used as a mask to obliquely implant an n-type impurity into the side of p-type region 23 so as to form an extension region in n-type region 23 (FIG. 17(b)).

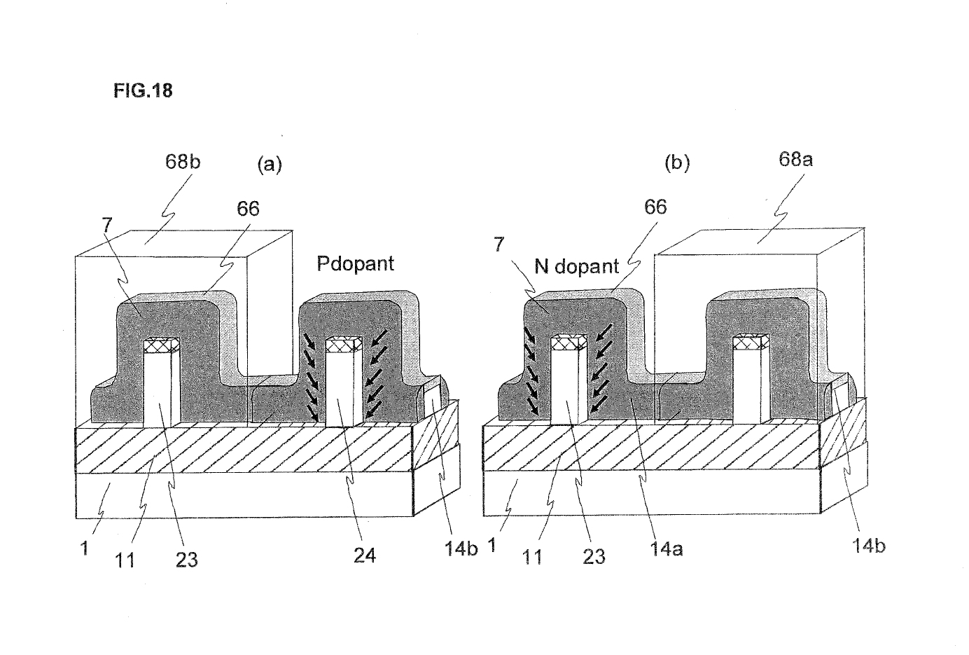

Gate sidewalls 7 are formed on both sides of first gate electrode material 14b, second gate electrode material 14a, and mask (F) 66. Lithography is then used to form mask (G) 68b that covers p-type region 23, second gate electrode material 14a, mask (F) 66, and gate sidewall 7. Mask (G) 68b and mask (F) 66 are then used as a mask to obliquely implant a p-type impurity into the side of n-type region 24 (FIG. 18(a)).

After mask (G) 68b is removed, lithography is used to form mask (H) 68a that covers n-type region 24, first gate electrode material 14b, mask (F) 66, and gate sidewall 7. Mask (H) 68a and mask (F) are then used as a mask to obliquely implant an n-type impurity into the side of n-type region 23 (FIG. 18(b)). Mask (H) 68a is then removed.

Heat treatment is then carried out to activate the p-type impurity implanted into n-type region 24 and the n-type impurity implanted into p-type region 23 so as to form source/drain regions 30b and 30a in n-type region 24 and p-type region 23, respectively.

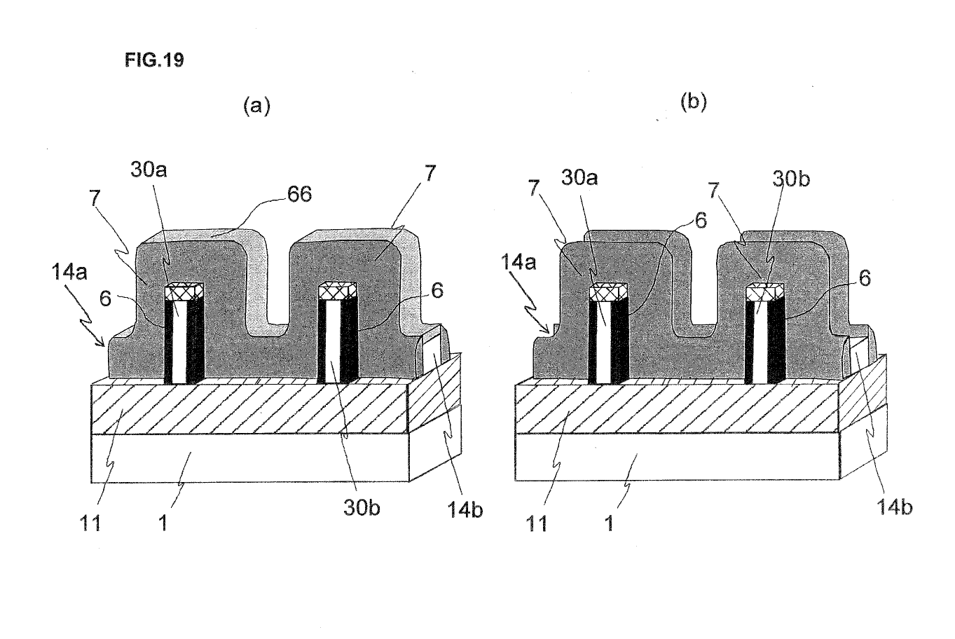

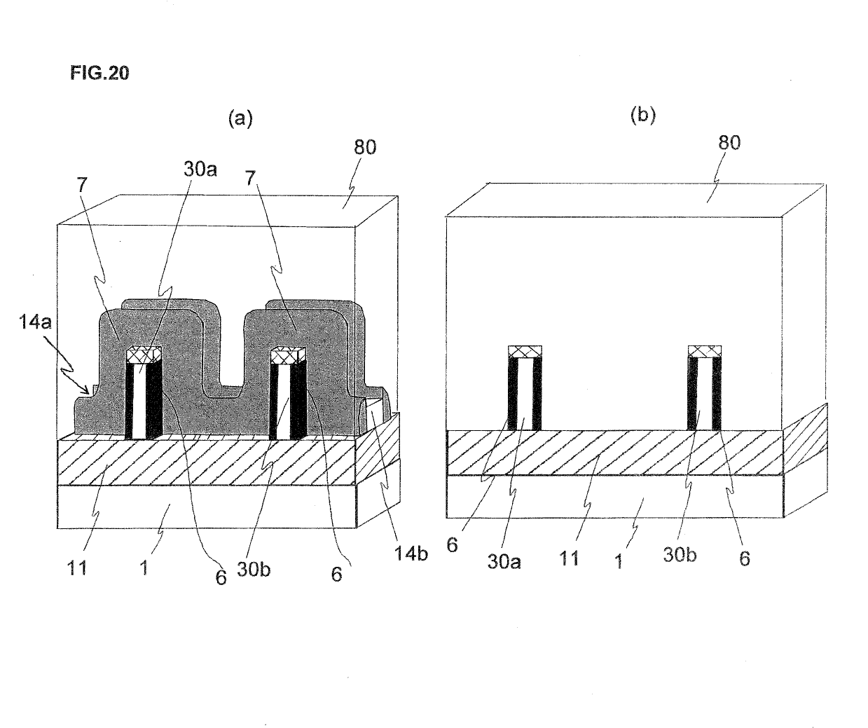

Salicide technique is then used to form silicide layers 6 on both sides of source/drain regions 30a and 30b (FIG. 19(a)). The silicide layer can be made of Co silicide or Ni silicide. When Ni silicide is used, a silicide protective layer is preferably formed on the silicide layer. After mask (F) 66 is removed (FIG. 19(b)), sputtering is used to deposit Ni layer 80 over the resulting surface (FIGS. 20(a), (b)).

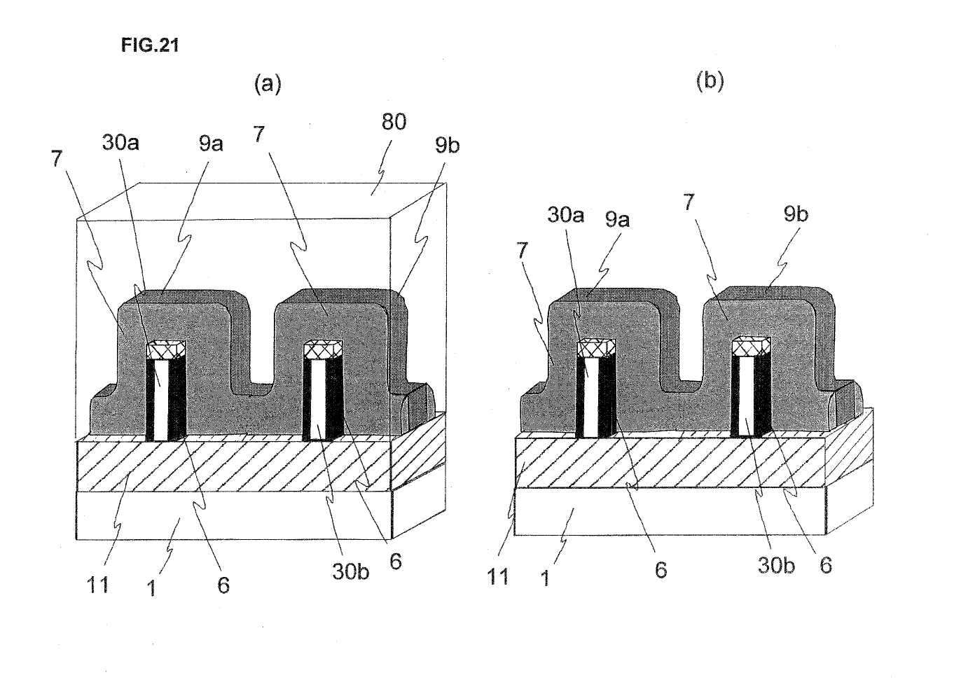

Heat treatment is then carried out to react Ni with the first and second gate electrode materials so that the first and second gate electrode materials are converted into silicide region (1) comprising an NiSi crystalline phase containing the n-type impurity and silicide region (2) comprising an NiSi crystalline phase containing the p-type impurity, respectively (FIG. 21(a)). The silicidation conditions are set so that an NiSi crystalline phase is selectively formed, as in the first exemplary embodiment. When silicide layers 6 are made of Co silicide or Ni silicide with a protective layer, the silicidation will not degrade silicide layers 6. Excess Ni film 80 that has not been converted into silicide is removed in a wet etching process using sulfuric acid in a hydrogen peroxide solution (FIG. 21(b)).

1-18. (canceled)

19. A semiconductor device, comprising:
a support substrate; an oxide film formed on the support substrate; and a pMOS transistor and an nMOS transistor formed on the oxide film, wherein the pMOS transistor is a fully depleted transistor, the pMOS transistor comprising:
an n-type region formed on the oxide film; a first gate electrode formed above the n-type region; a first gate insulating film formed between the n-type region and the first gate electrode; and a source/drain region formed throughout in both portions of the n-type region sandwiching the first gate electrode in the direction of a normal to the surface where the n-type region is in contact with the first gate insulating film, the nMOS transistor is a fully depleted transistor,
the nMOS transistor comprising:
a p-type region formed on the oxide film;
a second gate electrode formed above the p-type region;
a second gate insulating film formed between the p-type region and the second gate electrode; and a source/drain region formed throughout in both portions of the p-type region sandwiching the second gate electrode in the direction of a normal to the surface where the p-type region is in contact with the second gate insulating film, the first gate electrode includes silicide region (1) comprising an NiSi crystalline phase containing an n-type impurity, the silicide region (1) being in contact with the first gate insulating film, and
the second gate electrode includes silicide region (2) comprising an NiSi crystalline phase containing a p-type impurity, the silicide region (2) being in contact with the second gate insulating film.

20. A semiconductor device, comprising:
a support substrate; an oxide film formed on the support substrate; and a pMOS transistor and an nMOS transistor formed on the oxide film, wherein the pMOS transistor comprises:
an n-type region formed on the oxide film;
a first gate electrode formed above the n-type region;
a first gate insulating film formed between the n-type region and the first gate electrode; and a source/drain region formed throughout in both portions of the n-type region sandwiching the first gate electrode in the direction of a normal to the surface where the n-type region is in contact with the first gate insulating film, the length of the n-type region in the direction of the normal to the surface where the n-type region is in contact with the first gate insulating film is one-fourth of a gate length of the pMOS transistor or smaller,
the first gate electrode includes silicide region (1) comprising an NiSi crystalline phase containing an n-type impurity, the silicide region (1) being in contact with the first gate insulating film, the nMOS transistor comprises:
a p-type region formed on the oxide film;
a second gate electrode formed above the p-type region;
a second gate insulating film formed between the p-type region and the second gate electrode; and a source/drain region formed throughout in both portions of the p-type region sandwiching the second gate electrode in the direction of a normal to the surface where the p-type region is in contact with the second gate insulating film, the length of the p-type region in the direction of the normal to the surface where the p-type region is in contact with the second gate insulating film is one-fourth of a gate length of the nMOS transistor or smaller, and the second gate electrode includes silicide region (2) comprising an NiSi crystalline phase containing a p-type impurity, the silicide region (2) being in contact with the second gate insulating film.

21. The semiconductor device according to claim 20, further comprising an isolation region that isolates the n-type region and the p-type region from each other, wherein the n-type region, the p-type region, and the isolation region form a single plane on the oxide film, the first and second gate electrodes are formed on the plane, and
the pMOS transistor and the nMOS transistor form planar MOS transistors.

22. The semiconductor device according to claim 20, wherein the n-type region and the p-type region are a protruding n-type region and a protruding p-type region separately formed and protruding from the oxide film, the first gate electrode and the first gate insulating film are formed on both sides of the protruding n-type region, and
the second gate electrode and the second gate insulating film are formed on both sides of the protruding p-type region.

23. The semiconductor device according to claim 19, wherein the entire first gate electrode comprises the silicide region (1) comprising the NiSi crystalline phase containing the n-type impurity, and the entire second gate electrode comprises the silicide region (2) comprising the NiSi crystalline phase containing the p-type impurity.

24. The semiconductor device according to claim 19, wherein the n-type impurity is at least one type of impurity elements selected from the group consisting of P, As, and Sb.

25. The semiconductor device according to claim 19, wherein the p-type impurity is B.

26. The semiconductor device according to claim 19, wherein the concentration of the n-type impurity in the silicide region (1) ranges from 2×10²⁰ to 1×10²¹ cm⁻³.

27. The semiconductor device according to claim 19, wherein the concentration of the p-type impurity in the silicide region (2) ranges from 2×10²⁰ to 1×10²¹ cm⁻³.

28. The semiconductor device according to claim 19, wherein the length of the n-type region in the direction of the normal to the surface where the n-type region is in contact with the first gate insulating film and the length of the p-type region in the direction of the normal to the surface where the p-type region is in contact with the second gate insulating film range from 5 to 20 nm.

29. The semiconductor device according to claim 19, wherein the pMOS transistor and the nMOS transistor form a CMOS transistor.

30. A method for manufacturing the semiconductor device according to claim 33, the method comprising:
preparing a substrate in which the support substrate, the oxide film, and a semiconductor layer with the n-type region and the p-type region are sequentially stacked; depositing an insulating film and a polysilicon layer over the surface of the semiconductor layer; forming mask (A) on the polysilicon layer formed on the n-type region; using the mask (A) as a mask to implant a p-type impurity into the polysilicon layer;
removing the mask (A); forming mask (B) on the polysilicon layer formed on the p-type region; using the mask (B) as a mask to implant an n-type impurity into the polysilicon layer;
removing the mask (B); forming a mask layer on the polysilicon layer; patterning the insulating film, the polysilicon layer, and the mask layer to form the first gate insulating film, a first gate electrode material, and mask (C) on the n-type region and the second gate insulating film, a second gate electrode material, and mask (C) on the p-type region;
forming gate sidewalls on the sides of the first gate insulating film, the first gate electrode material, and the mask (C) and on the sides of the second gate insulating film, the second gate electrode material, and the mask (C); forming mask (D) over the surface of the n-type region; using the masks (C) and (D) and the gate sidewall as a mask to implant an n-type impurity into the p-type region; removing the mask (D); forming mask (E) over the surface of the p-type region;
using the masks (C) and (E) and the gate sidewall as a mask to implant a p-type impurity into the n-type region; removing the mask (E); forming the source/drain regions in the p-type and n-type regions by carrying out heat treatment to activate the n-type impurity implanted into the p-type region and the p-type impurity implanted into the n-type region, as a formation step; depositing an interlayer insulating film over the surface of the semiconductor layer; removing the mask (C) and part of the interlayer insulating film to expose the first and second gate electrode materials; depositing an Ni layer on the exposed first and second gate electrode materials; converting the first gate electrode material into the silicide region (1) comprising the NiSi crystalline phase containing the n-type impurity and the second gate electrode material into the silicide region (2) comprising the NiSi crystalline phase containing the p-type impurity, by carrying out heat treatment to react the first and second gate electrode materials with Ni, as a silicidation step; and removing the unreacted Ni layer in the silicidation step.

31. The method for manufacturing the semiconductor device according to claim 30, after the formation step in which the source/drain regions are formed, the method further comprising:
forming silicide layers on the source/drain region in the p-type region and the source/drain region in the n-type region.

32. A method for manufacturing the semiconductor device according to claim 34, the method comprising:
preparing a substrate in which the support substrate, the oxide film, and a semiconductor layer with the n-type region and the p-type region are sequentially stacked; forming a mask pattern on the semiconductor layer; using the mask pattern as a mask to pattern the semiconductor layer to form the protruding n-type region and the protruding p-type region;
forming the first gate insulating film, a first gate electrode material containing an n-type impurity, and mask (F) in this order on both sides of a central portion of the protruding n-type region; forming the second gate insulating film, a second gate electrode material containing a p-type impurity, and mask (F) in this order on both sides of a central portion of the protruding p-type region; forming mask (G) that covers the protruding p-type region, the second gate insulating film, the second gate electrode material, and the mask (F); using the masks (F) and (G) as a mask to implant a p-type impurity into both portions of the protruding n-type region sandwiching the first gate electrode material to form the source/drain region;
removing the mask (G); forming mask (H) that covers the protruding n-type region, the first gate insulating film, the first gate electrode material, and the mask (F); using the masks (F) and (H) as a mask to implant an n-type impurity into both portions of the protruding p-type region sandwiching the second gate electrode material to form the source/drain region; removing the mask (H); removing the mask (F);
depositing an Ni layer over the surface of the first and second gate electrode materials; converting the first gate electrode material into the silicide region (1) comprising the NiSi crystalline phase containing the n-type impurity and the second gate electrode material into the silicide region (2) comprising the NiSi crystalline phase containing the p-type impurity, by carrying out heat treatment to react the first and second gate electrode materials with Ni, as a silicidation step; and removing the unreacted Ni layer in the silicidation step.

33. The semiconductor device according to claim 19, further comprising an isolation region that isolates the n-type region and the p-type region from each other, wherein the n-type region, the p-type region, and the isolation region form a single plane on the oxide film,
the first and second gate electrodes are formed on the plane, and the pMOS transistor and the nMOS transistor form planar MOS transistors.

34. The semiconductor device according to claim 19, wherein the n-type region and the p-type region are a protruding n-type region and a protruding p-type region separately formed and protruding from the oxide film, the first gate electrode and the first gate insulating film are formed on both sides of the protruding n-type region, and
the second gate electrode and the second gate insulating film are formed on both sides of the protruding p-type region.

35. The semiconductor device according to claim 22, wherein the entire first gate electrode comprises the silicide region (1) comprising the NiSi crystalline phase containing the n-type impurity, and the entire second gate electrode comprises the silicide region (2) comprising the NiSi crystalline phase containing the p-type impurity.

36. The semiconductor device according to claim 33, wherein the entire first gate electrode comprises the silicide region (1) comprising the NiSi crystalline phase containing the n-type impurity, and the entire second gate electrode comprises the silicide region (2) comprising the NiSi crystalline phase containing the p-type impurity.

37. The semiconductor device according to claim 34, wherein the entire first gate electrode comprises the silicide region (1) comprising the NiSi crystalline phase containing the n-type impurity, and the entire second gate electrode comprises the silicide region (2) comprising the NiSi crystalline phase containing the p-type impurity.

38. The semiconductor device according to claim 22, wherein the n-type impurity is at least one type of impurity elements selected from the group consisting of P, As and Sb.

39. The semiconductor device according to claim 33, wherein the n-type impurity is at east one type of impurity elements selected from the group consisting of P, As, and Sb.

40. The semiconductor device according to claim 34, wherein the n-type impurity is at least one type of impurity elements selected from the group consisting of P, As, and Sb.

41. The semiconductor device according to claim 22, wherein the p-type impurity is B.

42. The semiconductor device according to claim 33, wherein the p-type impurity is B.

43. The semiconductor device according to claim 34, wherein the p-type impurity is B.

44. The semiconductor device according to claim 22, wherein the concentration of the n-type impurity in the silicide region (1) ranges from 2×10²⁰ to 1×10²¹ cm⁻³.

45. The semiconductor device according to claim 33, wherein the concentration of the n-type impurity in the silicide region (1) ranges from 2×10²⁰ to 1×10²¹ cm⁻³.

46. The semiconductor device according to claim 34, wherein the concentration of the n-type impurity in the silicide region (1) ranges from 2×10²⁰ to 1×10²¹ cm⁻³.

47. The semiconductor device according to claim 22, wherein the concentration of the p-type impurity in the silicide region (2) ranges from 2×10²⁰ to 1×10²¹ cm⁻³.

48. The semiconductor device according to claim 33, wherein the concentration of the p-type impurity in the silicide region (2) ranges from 2×10²⁰ to 1×10²¹ cm⁻³.

49. The semiconductor device according to claim 34, wherein the concentration of the p-type impurity in the silicide region (2) ranges from 2×10²⁰ to 1×10²¹ cm⁻³.

50. The semiconductor device according to claim 22, wherein the length of the n-type region in the direction of the normal to the surface where the n-type region is in contact with the first gate insulating film and the length of the p-type region in the direction of the normal to the surface where the p-type region is in contact with the second gate insulating film range from 5 to 20 nm

51. The semiconductor device according to claim 33, wherein the length of the n-type region in the direction of the normal to the surface where the n-type region is in contact with the first gate insulating film and the length of the p-type region in the direction of the normal to the surface where the p-type region is in contact with the second gate insulating film range from 5 to 20 nm.

52. The semiconductor device according to claim 34, wherein the length of the n-type region in the direction of the normal to the surface where the n-type region is in contact with the first gate insulating film and the length of the p-type region in the direction of the normal to the surface where the p-type region is in contact with the second gate insulating film range from 5 to 20 nm.

53. The semiconductor device according to claim 22, wherein the pMOS transistor and the nMOS transistor form a CMOS transistor

54. The semiconductor device according to claim 33, wherein the pMOS transistor and the nMOS transistor form a CMOS transistor.

55. The semiconductor device according to claim 34, wherein the pMOS transistor and the nMOS transistor form a CMOS transistor.
